(19) United States
(12) Patent Application Publication
(10) Pub. No.: US 2025/0357409 A1
(43) Pub. Date: Nov. 20, 2025

(54) SEMICONDUCTOR PACKAGE AND METHOD OF FORMING THE SAME

(71) Applicant: Taiwan Semiconductor Manufacturing Co., Ltd., Hsinchu (TW)

(72) Inventors: Chen-Hua Yu, Hsinchu (TW); Tung-Liang Shao, Hsinchu (TW); Yu-Sheng Huang, Hemei Township (TW)

(21) Appl. No.: 19/284,045

(22) Filed: Jul. 29, 2025

Related U.S. Application Data
(63) Continuation of application No. 18/659,287, filed on May 9, 2024.
(60) Provisional application No. 63/549,620, filed on Feb. 5, 2024.
(60) Provisional application No. 63/558,801, filed on Feb. 28, 2024.

(51) Int. Cl. H01L 23/00; H01L 23/31

(52) U.S. Cl. CPC H01L 24/24; H01L 23/3121; H01L 24/82; H01L 2224/24137; H01L 2224/24246; H01L 2224/8283; H01L 2924/1903

(57) ABSTRACT

A package includes a redistribution structure that includes conductive features and first waveguides; first dies and second dies attached to the redistribution structure, wherein the first dies are different than the second dies, wherein the first dies are electrically connected to respectively corresponding second dies through the redistribution structure; and optical bridge structures attached to the redistribution structure, wherein the optical bridge structures are optically coupled to the first waveguides, wherein the optical bridge structures are electrically connected to respectively corresponding first dies and respectively corresponding second dies through the redistribution structure.

### PRIORITY CLAIM AND CROSS-REFERENCE

This application is a continuation of U.S. patent application Ser. No. 18/659,287, filed on May 9, 2024, which claims the benefits of U.S. Provisional Application No. 63/549,620, filed on Feb. 5, 2024, and the benefits of U.S. Provisional Application No. 63/558,801, filed on Feb. 28, 2024, which applications are hereby incorporated herein by reference in their entirety.

### BACKGROUND

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) components and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, and 8 illustrate intermediate steps in the formation of an optical bridge structure, in accordance with some embodiments.

FIGS. 9, 10, 11, 12, 13, 14, 15A, and 15B illustrate cross-sectional views of intermediate steps in the formation of a package, in accordance with some embodiments.

FIG. 16 illustrates a plan view of a package, in accordance with some embodiments.

FIG. 17 illustrates a cross-sectional view of a package, in accordance with some embodiments.

FIG. 18 illustrates a cross-sectional view of a package, in accordance with some embodiments.

FIG. 19 illustrates a plan view of a package, in accordance with some embodiments.

FIGS. 20, 21, 22, 23, 24, 25A, and 25B illustrate cross-sectional views of intermediate steps in the formation of a package, in accordance with some embodiments.

FIG. 26 illustrates a plan view of a package, in accordance with some embodiments.

FIG. 27 illustrates a plan view of a package, in accordance with some embodiments.

FIGS. 28, 29, 30, 31, 32, and 33 illustrate cross-sectional views of intermediate steps in the formation of a package, in accordance with some embodiments.

FIG. 34 illustrates a cross-sectional view of a system, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Additionally, arrows are used throughout the figures to indicate the paths of light (e.g., optical signals and/or optical power). It should be understood that for clarity the transmission of light is described along a path in one direction as indicated by arrows, but in some cases, light may also be transmitted in the reverse direction along the path.

Various structures such optical bridge structures, packages, and systems and their methods of formation are described herein. A package includes components and optical bridge structures attached to a redistribution structure. The redistribution structure includes waveguides that allow for optical communication within the package. The waveguides are optically coupled to the optical bridge structures, and the optical bridge structures act as an interface between the components and the waveguides. In this manner, both electrical and optical communication is facilitated between multiple components of a package. In some embodiments, within a package, electrical signals may be used for some short-distance communication and optical signals may be used for some long-distance communication.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

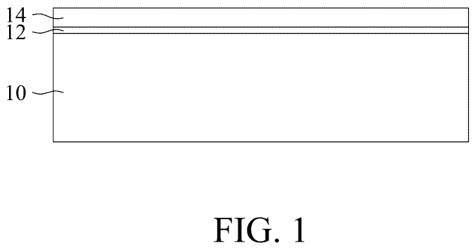

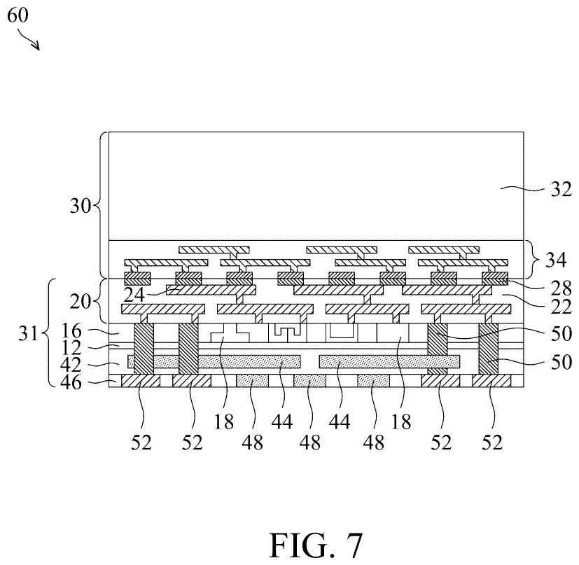

FIGS. 1 through 7 illustrate intermediate steps in the formation of an optical bridge structure 60 (see FIG. 7), in accordance with some embodiments. The optical bridge structure 60 comprises photonic components and waveguides that may be configured to receive, generate, modify, transmit, and/or process optical signals. In this manner, the optical bridge structure 60 may provide an interface for optical communication in a system. In some cases, the optical bridge structure 60 may be considered an optical engine, an optical interposer, or the like.

Turning to FIG. 1, the optical bridge structure 60 comprises at this stage a first substrate 10, a dielectric layer 12, and photonic layer 14. In an embodiment, at a beginning of the manufacturing process of the optical bridge structure 60, the first substrate 10, the dielectric layer 12, and the photonic layer 14 may collectively be part of a silicon-on-insulator (SOI) substrate or the like, which may be doped (e.g., with a p-type or an n-type dopant) or undoped. The first substrate 10 may be a wafer, such as a silicon wafer. Other substrates, such as a silicon-on-insulator (SOI) substrate, a multi-layered substrate, or a gradient substrate may also be used. In some embodiments, the semiconductor material of the first substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the first substrate 10 may be a dielectric material such as silicon oxide, glass, ceramic, plastic, or any other suitable material that allows for structural support of overlying devices. In some embodiments, multiple optical bridge structures 60 may be formed on a single first substrate 10 and then may be subsequently singulated into individual optical bridge structures 6o. The first substrate 10 may be free of passive or active devices, in some cases.

The dielectric layer 12 may be a dielectric layer that separates the first substrate 10 from the overlying photonic layer 14 and can additionally, in some embodiments, serve as a portion of cladding material that surrounds the subsequently manufactured photonic components 18 (described below). In an embodiment, the dielectric layer 12 may be silicon oxide, silicon nitride, germanium oxide, germanium nitride, combinations of these, or the like. The dielectric layer 12 may be formed using a technique such as implantation (e.g., to form a buried oxide (BOX) layer) or using a suitable deposition technique such as chemical vapor deposition (CVD), atomic layer deposition (ALD), physical vapor deposition (PVD), combinations of these, or the like. However, any suitable material and method of manufacture may be used.

In some embodiments, the photonic layer 14 may be a semiconductor material such as silicon, germanium, silicon germanium, combinations of these, or the like. In other embodiments, the photonic layer 14 may comprise a dielectric material such as silicon nitride or the like, a III-V semiconductor material, lithium niobate materials, polymers, the like, or combinations thereof. The photonic layer 14 may be formed using a suitable technique, such as epitaxial growth, CVD, ALD, PVD, the like, or combinations thereof. Other materials or techniques are possible.

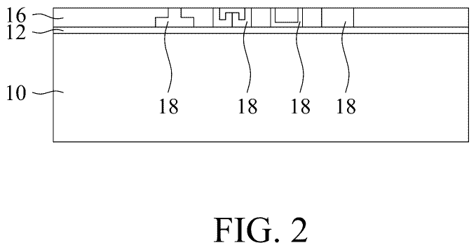

FIG. 2 illustrates the formation of photonic components 18 from the photonic layer 14, in accordance with some embodiments. In some embodiments, the photonic components 18 may include such devices or components as optical waveguides (e.g., ridge waveguides, rib waveguides, buried channel waveguides, diffused waveguides, etc.), couplers (e.g., grating couplers, edge couplers comprising a tip waveguide having a width in the range of about 1 nm to about 200 nm, etc.), directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. However, the photonic components 18 may comprise other devices structures, or components than these examples.

In some embodiments, the photonic components 18 may be formed by patterning the photonic layer 14 into the appropriate shapes for the photonic components 18. For example, photonic layer 14 may be patterned using one or more photolithographic masking and etching processes, though any suitable method of patterning the photonic layer 14 may be utilized. The patterning may expose portions of the dielectric layer 12. In some cases, additional processing steps may be performed to form some types of photonic components 18, such as additional implantation processes, deposition processes, and/or patterning processes. In some embodiments, one or more photonic components 18 may be formed by patterning the photonic layer 14 and then depositing another material on portions of the patterned photonic layer 14. For example, the formation of a photonic components 18 may comprise patterning a photonic layer 14 comprising silicon and then epitaxially growing a region of germanium on the patterned photonic layer 14, though other materials or process steps are possible.

Sill referring to FIG. 2, a dielectric layer 16 may be formed over the dielectric layer 12 and/or the photonic components 18, in accordance with some embodiments. The dielectric layer 16 may be, for example, a dielectric layer that separates the individual photonic components 18 from each other and from the overlying structures. Further, in some cases, the dielectric layer 16 can additionally serve as a cladding material that at least partially surrounds one or more photonic components 18. In some embodiments, the dielectric layer 16 may comprise silicon oxide, silicon nitride, germanium oxide, germanium nitride, combinations of these, or the like, which may be formed using suitable deposition techniques such as CVD, ALD, PVD, or the like. Other materials or deposition techniques are possible. In some embodiments, after depositing the dielectric layer 16, a planarization process (e.g., a chemical mechanical polishing (CMP) process, a grinding process, or the like) may be performed to planarize a top surface of the dielectric layer 16. In some embodiments, the planarization process may expose a top surface of one or more photonic components 18. In such embodiments, the top surfaces of the photonic components 18 and the top surfaces of the dielectric layer 16 may be level or coplanar (within process variations). In some embodiments, one or more photonic components 18 remain covered by the dielectric layer 16 after performing the planarization process.

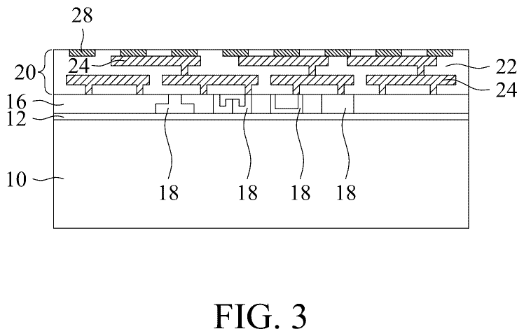

FIG. 3 illustrates the formation of an interconnect structure 20 over the photonic components 18, in accordance with some embodiments. The interconnect structure 20 includes dielectric layers 22 (not individually illustrated) with conductive features 24 formed in the dielectric layers 22, in some embodiments. The conductive features 24 allow for electrical communication within the optical bridge structure 60. The conductive features 24 may comprise conductive lines, conductive vias, conductive pads, metallization patterns, redistribution layers, or the like that provide electrical interconnections and electrical routing within the optical bridge structure 6o. Conductive features 24 may be electrically connected to one or more photonic components 18, in some cases. The interconnect structure 20 may also comprise conductive pads 28 at a top surface of the interconnect structure 20, in some embodiments. The conductive pads 28 may be metal pads, bonding pads, or the like.

In some embodiments, the interconnect structure 20 is formed of alternating layers of dielectric material (e.g., dielectric layers 22) and conductive material (e.g., conductive features 24). The conductive features 24 may be formed using any suitable processes such as deposition, damascene, dual damascene, or the like. In particular embodiments, the interconnect structure 20 may have multiple layers of conductive features 24, but the precise number of layers of conductive features 24 may be dependent upon the design of the optical bridge structure 60. The dielectric layers 22 may be, for example, insulating layers and/or passivating layers, and may comprise silicon oxide, silicon nitride, a polymer, the like, or a combination thereof. The conductive features 24 may include, for example, a metal or a metal alloy such as copper, silver, gold, tungsten, cobalt, ruthenium, aluminum, alloys thereof, combinations thereof, or the like. Other materials are possible.

In some embodiments, the conductive pads 28 are formed in the topmost dielectric layer 22 of the dielectric layers 22. In some embodiments, the conductive pads 28 electrically contact underlying conductive features 24. The conductive pads 28 may comprise one or more layers of conductive materials such as those described above for the conductive features 24, or the like. In some cases, the conductive pads 28 are considered part of the conductive features 24. Other types of conductive pads 28 are possible.

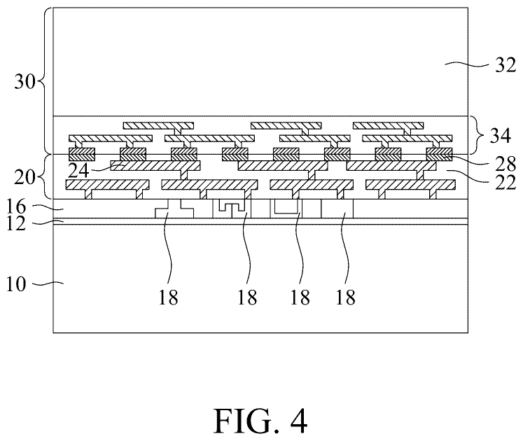

In FIG. 4, an electronic die 30 is bonded to the interconnect structure 20, in accordance with some embodiments. The electronic die 30 may comprise a substrate 32 and an interconnect structure 34 formed on one side of the substrate 32, in some embodiments. The substrate 32 may be similar to those described previously for the substrate 10, such as a silicon wafer or the like. In some embodiments, integrated circuits (not separately illustrated) may be formed in the substrate 32 using suitable techniques. For example, the electronic die 30 may include controllers, drivers, transimpedance amplifiers, transistors, other active devices, resistors, capacitors, other passive devices, the like, or combinations thereof. Accordingly, the electronic die 30 may be considered an electronic integrated circuit (EIC) structure or the like. In some embodiments, the integrated circuits may be configured to interface with the photonic components 18. For example, the integrated circuits may be configured to control the operation of the photonic components 18, to process electronic signals received from the photonic components 18, or the like. The integrated circuits may be configured to control high-frequency signaling of the photonic components 18 according to electrical signals (digital or analog) received from another device or die (e.g., first package component(s) 110 and/or second package component(s) 130, described below), in some embodiments. In this manner, an optical bridge structure 60 may process or transmit electrical signals based on received optical signals and/or may process or transmit optical signals based on received electrical signals. In some embodiments, the electronic die 30 may provide Serializer/Deserializer (SerDes) functionality. In some embodiments, an electronic die 30 may comprise one or more processing devices, such as a Central Processing Unit (CPU or “xPU”), a Graphics Processing Unit (GPU), an Application-Specific Integrated Circuit (ASIC), a High-Performance Computing (HPC) die, a logic die, the like, or a combination thereof. An electronic die 30 may include one or more memory devices, which may be a volatile memory such as Dynamic Random-Access Memory (DRAM), Static Random-Access Memory (SRAM), High-Bandwidth Memory (HBM), another type of memory, or the like.

The interconnect structure 34 of the electronic die 30 may comprise conductive features formed in one or more dielectric layers. The conductive features may comprise conductive lines, conductive vias, conductive pads, metallization patterns, redistribution layers, or the like that provide electrical interconnections and electrical routing. In some embodiments, the interconnect structure 34 is formed of alternating layers of dielectric material and conductive material. The conductive features may be formed using any suitable processes such as deposition, damascene, dual damascene, or the like. In some cases, the conductive features may be formed using materials or techniques similar to those described previously for the interconnect structure 20.

In some embodiments, the interconnect structure 34 may include bond pads formed in a bonding layer, and the electronic die 30 is bonded to the interconnect structure 20 by dielectric-to-dielectric bonding and/or metal-to-metal bonding (e.g., direct bonding, fusion bonding, oxide-to-oxide bonding, hybrid bonding, or the like). In some embodiments, a bonding layer (e.g., an exposed dielectric layer) of the interconnect structure 34 is bonded to a bonding layer (e.g., an exposed dielectric layer) of the interconnect structure 20 using a dielectric-to-dielectric bonding process, and conductive pads of the interconnect structure 34 are bonded to corresponding conductive pads 28 of the interconnect structure 20 using a metal-to-metal bonding process. In some embodiments, the bonding process may be initiated by activating the bonding surfaces of the bonding layers of the interconnect structure 34 and the interconnect structure 20, which can facilitate bonding of the bonding surfaces. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments. After the activation process, the electronic die 30 is aligned and placed into physical contact with the interconnect structure 20. The electronic die 30 and the interconnect structure 20 are then subjected to a thermal treatment and contact pressure to bond respective bonding layers together with dielectric-to-dielectric bonding and bond the conductive pads of the electronic die 30 to the conductive pads 28 of the interconnect structure 20 with metal-to-metal bonding. In some embodiments, the resulting bonded structure is subsequently baked, annealed, pressed, or otherwise treated to strengthen or finalize the bond. This is an example, and other bonding processes are possible. In other embodiments, the electronic dies 30 may comprise conductive connectors (e.g. solder bumps or the like), and may be bonded to the interconnect structure 20 using these conductive connectors.

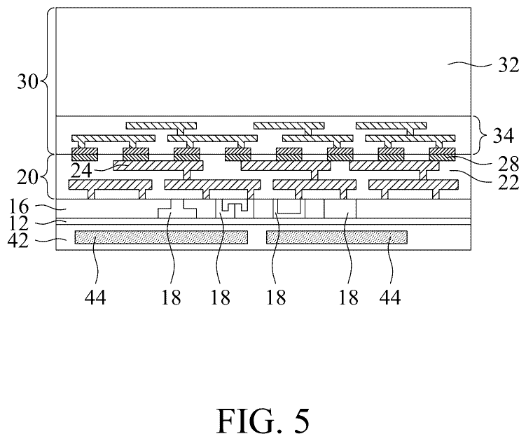

In FIG. 5, the substrate 10 is removed and waveguides 44 are formed, in accordance with some embodiments. The substrate 10 may be removed using a planarization process (e.g., a CMP process, a grinding process, or the like) and/or an etching process. In some embodiments, removing the substrate 10 exposes the dielectric layer 12. In some embodiments, removing the substrate 10 also thins the dielectric layer 12. In some embodiments, the dielectric layer 12 is used as a stop layer during removal of the substrate 10.

After removing the substrate 10, waveguides 44 are then formed over the dielectric layer 12, in accordance with some embodiments. The waveguides 44 may allow for optical communication within the optical bridge structure 60 and may be optically coupled to photonic components 18. For example, waveguides 44 may receive optical signals from photonic component(s) 18 and/or transmit optical signals to photonic component(s) 18. FIG. 5 shows a single layer of waveguides 44 formed within a plurality of dielectric layers 42 (not individually illustrated), however, multiple layers of waveguides 44 may be formed in other embodiments. For example, one or more layers of waveguides 44 may be formed within multiple dielectric layers 42 (not individually illustrated). In some embodiments, a waveguide 44 may be optically coupled to an adjacent waveguide 44, to an overlying waveguide 44 of another layer, and/or to an underlying waveguide 44 of another layer.

In some embodiments, a layer of waveguides 44 may be formed by depositing a waveguide material on a dielectric layer 42 and then patterning the waveguide material. In some embodiments, the waveguide material may be deposited on the dielectric layer 12 and thus the resulting waveguides 44 are formed on the dielectric layer 12. In other cases, the waveguide material is deposited on a previously deposited dielectric layer 42. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. The waveguide material may be deposited using a suitable technique, such as ALD, PVD, or the like. The waveguide material may then be patterned using suitable photolithography and etching techniques to form a layer of waveguides 44. Another dielectric layer 42 may then be deposited on the waveguides 44. The steps of depositing a waveguide material, patterning the waveguide material to form a layer of waveguides 44, and then depositing a dielectric layer 42 over the layer of waveguides 44 may be repeated to form multiple layers of waveguides 44.

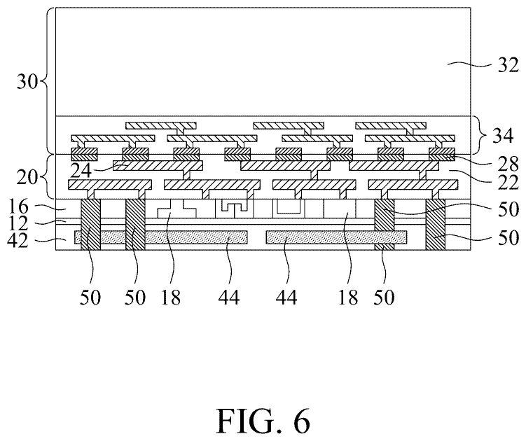

In FIG. 6, vias 50 are formed extending through the dielectric layer(s) 42, the dielectric layer 12, and the dielectric layer 16, in accordance with some embodiments. The vias 50 may physically and electrically contact conductive features 24 of the interconnect structure 20. In some embodiments, the vias 50 may extend into one or more of the dielectric layers 22 of the interconnect structure 20. The vias 50 may be formed, for example, by forming openings extending through the dielectric layer(s) 42, the dielectric layer 12, and the dielectric layer 16, and/or one or more dielectric layers 22 to expose surfaces of the conductive features 24. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be deposited in the openings, thereby forming the vias 50. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive, such that surfaces of the vias 50 and a dielectric layer 42 are level. Other materials or techniques are possible. In other embodiments, the vias 50 are formed at another stage of the manufacturing process than the embodiment shown.

In FIG. 7, bonding pads 52 and waveguides 48 are formed, in accordance with some embodiments. In some embodiments, a bonding layer 46 may be formed over the dielectric layer(s) 42, in accordance with some embodiments. The bonding pads 52 and waveguides 48 may be formed in the bonding layer 46. The bonding layer 46 may comprise one or more layers of suitable materials, such as silicon oxide, silicon oxynitride, the like, or a combination thereof.

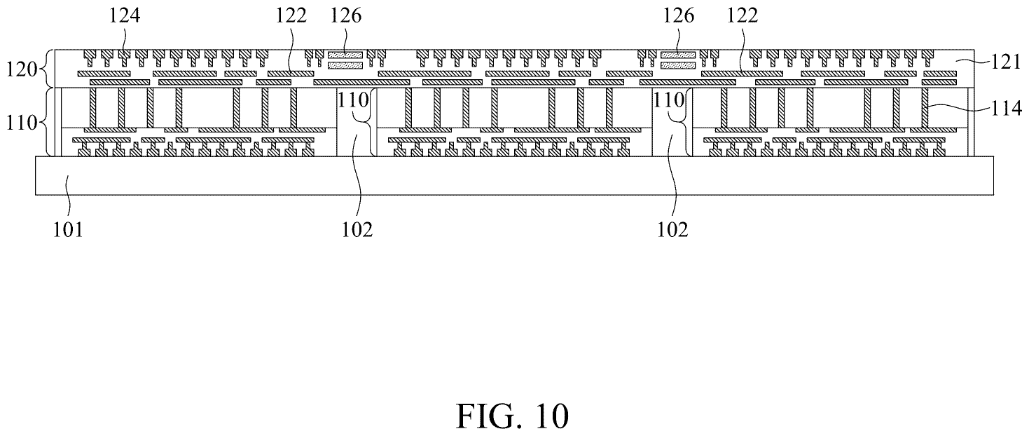

In some embodiments, one or more waveguides 48 may be formed over the dielectric layer(s) 42. The waveguides 48 are optically coupled to one or more overlying waveguides 48, and may be optically coupled to one or more underlying waveguides of another structure, such as waveguides 126 of the redistribution structure 120 (see FIG. 10). The waveguides 48 may be similar to the waveguides 48, and may be formed using similar materials or techniques. For example, a waveguide material may be deposited over the dielectric layer(s) 42 and then patterned to form the waveguides 48. The bonding layer 46 may then be deposited over the waveguides 48. In some embodiments, the bonding layer 46 may be planarized (e.g. using a CMP or grinding process) to expose the waveguides 48. In other embodiments, the waveguides 48 may remain covered by the bonding layer 46 after planarization.

In some embodiments, bonding pads 52 may be formed in the bonding layer 46. The bonding pads 52 may be similar to the conductive pads 28 and may be formed using similar materials or techniques. For example, openings may be patterned in the bonding layer 46 to expose the vias 50 using acceptable photolithography and etching techniques, and then the material of the bonding pads 52 may be deposited in the openings. In some embodiments, a planarization process (e.g., a CMP or grinding process) may be performed to remove excess material, and top surfaces of the bonding pads 52 and the bonding layer 46 may be substantially level or coplanar after planarization.

In this manner, an optical bridge structure 60 may be formed, in accordance with some embodiments. In some embodiments, multiple optical bridge structure 60 may be formed on a single first substrate 10 and then singulated into individual optical bridge structures 6o. In some cases, the interconnect structure 20, photonic components 18, waveguides 44/48, vias 50, and associated dielectric layers may be considered a photonic integrated circuit (PIC) structure 31. In this manner, the optical bridge structure 60 may be considered to be an EIC structure 30 bonded to a PIC structure 31, in some cases. The optical bridge structure 60 described for FIGS. 1-7 is an example, and other process steps, materials, configurations, or arrangements are possible in other optical bridge structures 60. For example, the electronic die 30 may be bonded at a different process step than shown, or the number or configuration of conductive features and/or waveguides may be different than shown. All suitable variations are considered within the scope of the present disclosure.

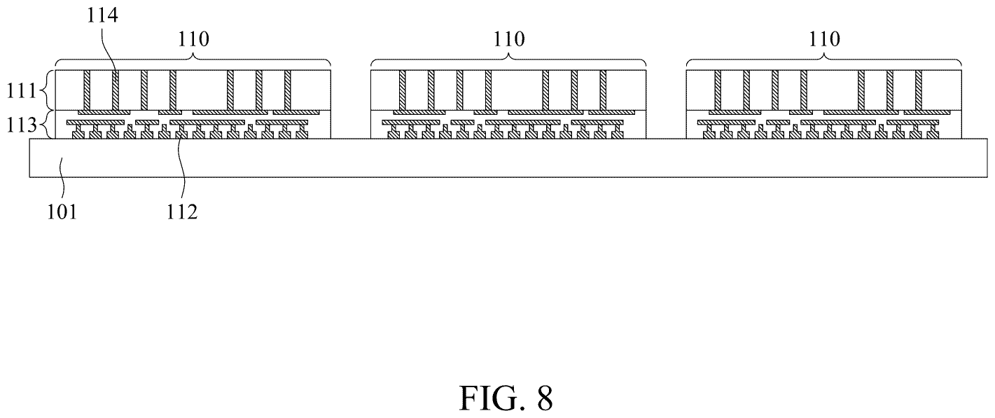

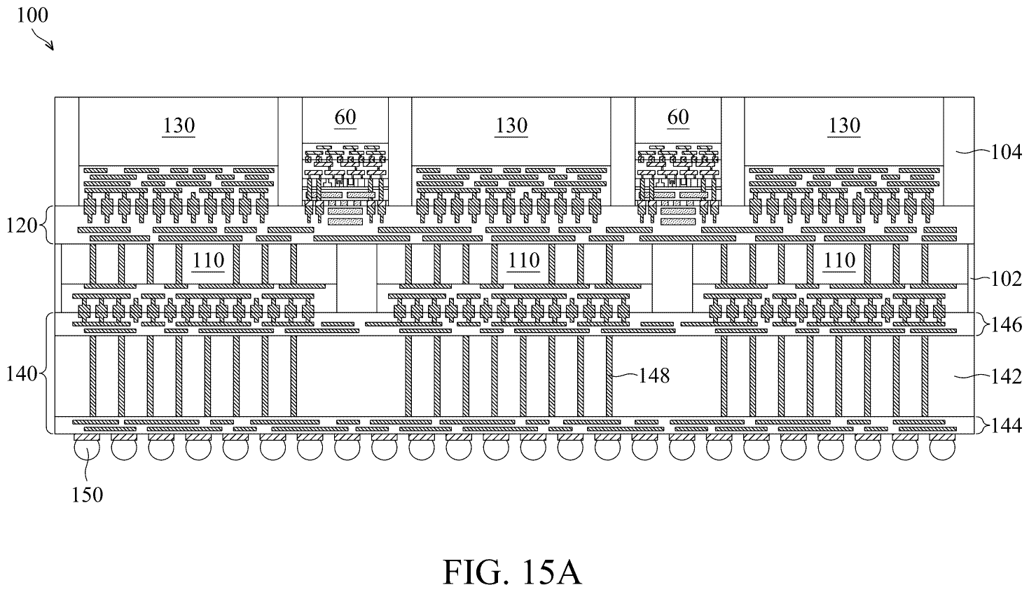

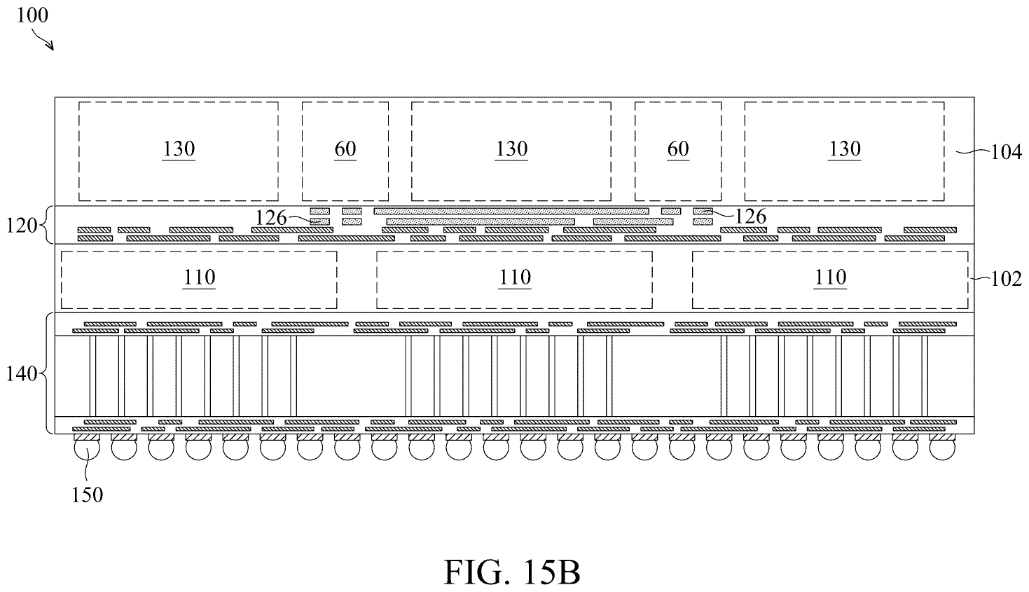

FIGS. 8 through FIGS. 15A-15B illustrate intermediate stages in the manufacturing of a package 100 (see FIGS. 15A-15B), in accordance with some embodiments. In FIG. 8, a plurality of first package components 110 are attached to a first carrier 101, in accordance with some embodiments. The first carrier 101 may be a supporting substrate, wafer, panel, or the like that is formed of any suitable materials, such as a semiconductor (e.g., silicon or the like), a glass, an oxide material (e.g., silicon oxide, aluminum oxide, or the like), a plastic, a polymer, an organic material, a metal, a film, the like, or a combination thereof. The first package components 110 may be attached to the first carrier 101 using an adhesive, a die attach film (DAF), or the like. FIGS. 8-12 illustrate three first package components 110 attached to the first carrier 101, but any suitable number of first package components 11o may be attached to the first carrier 101 in other embodiments.

The first package components 110 may include, for example, a chip, a die, a system-on-chip (SoC) device, a system-on-integrated-circuit (SoIC) device, a package, the like, or a combination thereof. The first package components 110 attached to the same first carrier 101 may be similar or different. In some embodiments, the first package components 110 comprise logic dies, memory dies, input-output (I/O) dies, Integrated Passive Devices (IPDs), or the like, or combinations thereof. For example, the first package components 110 may comprise logic dies such as Central Processing Unit (CPU or xPU) dies, Graphic Processing Unit (GPU) dies, mobile application dies, high performance computing (HPC) dies, Micro Control Unit (MCU) dies, BaseBand (BB) dies, Application processor (AP) dies, Application-Specific Integrated Circuit (ASIC) dies, or the like. The first package components 110 may comprise memory dies such as Static Random-Access Memory (SRAM) dies, Dynamic Random-Access Memory (DRAM) dies, High-Bandwidth Memory (HBM) dies, or the like. Other types or configurations of first package components 110 are possible.

In some embodiments, the first package components 11o comprise bonding pads 112 and through vias 114. The bonding pads 112 may be formed at a first side of a first package component 110, and may be formed within a bonding layer (not individually illustrated) of the first package component 110. Surfaces of the bonding pads 112 and the bonding layer may be substantially coplanar. The bonding pads 112 allow physical and electrical connection to be made between a first package component 110 and another structure at the first side of the first package component 110. The bonding pads 112 may be part of an interconnect structure 113 of the first package component 110, in some embodiments. The through vias 114 of a first package component 110 may extend through a portion of the first package component 110 to a second side of the first package component 110 opposite the first side. For example, the through vias 114 may extend through a substrate 111 of the first package component 110. The through vias 114 allow physical and electrical connection to be made between a first package component 110 and another structure at the second side of the first package component 110. The through vias 114 may be electrically coupled to an interconnect structure 113 of the first package component 110, in some embodiments. In some embodiments, the through vias 114 are not exposed at the second side of a first package component 110 and are covered by portions of the substrate 111. In other embodiments, the first package components 110 may have different configurations, functionalities, features, or arrangements than described or shown.

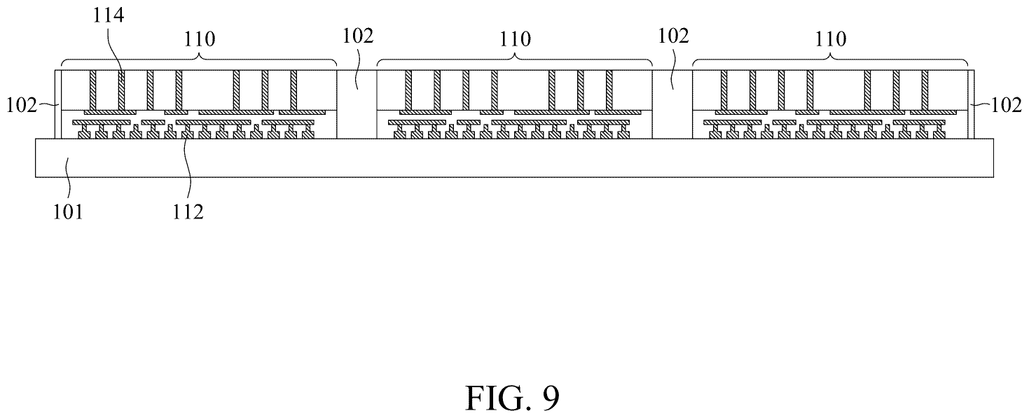

In FIG. 9, an encapsulant 102 is formed on and around the first package components 110, in accordance with some embodiments. After formation, the encapsulant 102 encapsulates the first package components 110. The encapsulant 102 may be a molding compound, an epoxy, a polymer, a composite material, a dielectric material, or the like. In some embodiments, the encapsulant 102 is applied by deposition, spin-on, compression molding, transfer molding, or the like. The encapsulant 102 may be formed over the first carrier 101 such that the first package components 110 are buried or covered. The encapsulant 102 is further formed in gap regions between neighboring first package components 110. The encapsulant 102 may be applied in liquid or semi-liquid form and then subsequently cured.

In some embodiments, a planarization process is performed on the encapsulant 102 to expose the through vias 114 of the first package components 110. In embodiments in which through vias 114 are covered by the substrate 111, the planarization process may also remove material of the substrate 111 until the through vias 114 are exposed. Top surfaces of the through vias 114, the substrates 111, and the encapsulant 102 may be substantially level or coplanar (within process variations) after performing the planarization process. The planarization process may comprise, for example, a chemical-mechanical polish (CMP) process, a grinding process, an etching process, or the like. In some embodiments, the planarization may be omitted, for example, if the through vias 114 are already exposed.

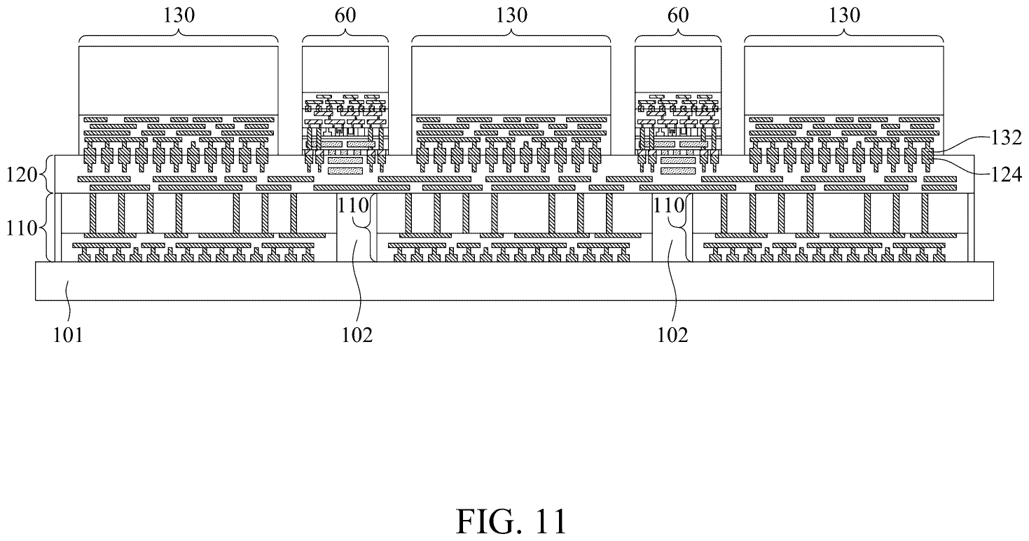

In FIG. 10, a redistribution structure 120 is formed over the first package components 110 and over the encapsulant 102, in accordance with some embodiments. FIG. 10 illustrates the redistribution structure 120 formed over the front side of the first package components 110, but the redistribution structure 120 may be formed over the back side of the first package components 110 in other embodiments. The redistribution structure 120 comprises conductive features 122, conductive pads 124, and waveguides 126 formed in a plurality of dielectric layers 121 (not individually illustrated). The conductive features 122 and conductive pads 124 provide electrical interconnections between underlying first package components 110, overlying second package components 130 (see FIG. 11), and/or overlying optical bridge structures 60 (see FIG. 11). The waveguides 126 provide long-distance optical communication within the redistribution structure 120 in conjunction with the optical bridge devices 60, described in greater detail below.

The conductive features 122 may include one or more layers of conductive lines, conductive vias, conductive pads, or the like, which may be considered metallization patterns or redistribution layers in some cases. Some conductive features 122 are electrically coupled to through vias 114 of underlying first package components 110. The conductive features 122 may be formed using any suitable process, such as deposition, plating, damascene, dual damascene, or the like. The conductive features 122 may be formed of conductive material(s) such as copper, silver, gold, tungsten, cobalt, ruthenium, aluminum, alloys thereof, combinations thereof, or the like, though other materials are possible. In some embodiments, the dielectric layers 121 may comprise suitable dielectric materials, such as silicon oxide, silicon oxynitride, silicon nitride, or the like. The number of layers of conductive features 122 may be different than shown, and the conductive features 122 may have a different configuration or arrangement than shown.

In some embodiments, the conductive pads 124 are formed in the topmost dielectric layer 121 of the dielectric layers 121, which may be a bonding layer. The conductive pads 124 are electrically coupled to underlying conductive features 122. In some cases, the conductive pads 124 may also be considered conductive features 122 of the redistribution structure 120. In some embodiments, the redistribution structure 120 is substantially free of active and passive devices.

As shown in FIG. 10, the redistribution structure 120 also comprises one or more layers of waveguides 126, in accordance with some embodiments. The waveguides 126 may be formed using materials or techniques similar to those described previously for the waveguides 44 or 48 of the optical bridge structure 60 (see FIG. 7). For example, in some embodiments, a layer of waveguides 126 may be formed by depositing a waveguide material on a dielectric layer 121 and then patterning the waveguide material. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. A waveguide 126 may be optically coupled to an overlying or underlying waveguide 126 of another layer of waveguides 126. A waveguide 126 of the topmost layer of waveguides 126 may be optically coupled to an overlying structure. For example, a waveguide 126 may be optically coupled to a waveguide 48 of an overlying optical bridge structure 60 (see FIG. 11). FIG. 10 shows two layers of waveguides 126, but the number of layers of waveguides 126 may be different than shown, and the waveguides 126 may have a different configuration or arrangement than shown.

In FIG. 11, a plurality of second package components 130 and a plurality of optical bridge structures 60 are bonded to the redistribution structure 120, in accordance with some embodiments. In this manner, the redistribution structure 120 may have first package components 110 attached to its back side and second package components 130 and optical bridge structures 60 attached to its front side. The second package components 130 may include, for example, a chip, a die, a system-on-chip (SoC) device, a system-on-integrated-circuit (SoIC) device, a package, the like, or a combination thereof. The second package components 130 attached to the same redistribution structure 120 may be similar or different. In some embodiments, the second package components 130 comprise logic dies, memory dies, input-output (I/O) dies, Integrated Passive Devices (IPDs), or the like, or combinations thereof. For example, the second package components 130 may comprise logic dies such as Central Processing Unit (CPU or xPU) dies, Graphic Processing Unit (GPU) dies, mobile application dies, high performance computing (HPC) dies, Micro Control Unit (MCU) dies, BaseBand (BB) dies, Application processor (AP) dies, Application-Specific Integrated Circuit (ASIC) dies, or the like. The second package components 130 may comprise memory dies such as Static Random-Access Memory (SRAM) dies, Dynamic Random-Access Memory (DRAM) dies, High-Bandwidth Memory (HBM) dies, or the like. Other types or configurations of second package components 130 are possible.

In some embodiments, the second package components 130 comprise bonding pads 132. The bonding pads 132 may be formed within a bonding layer (not individually illustrated) of the second package component 130. Surfaces of the bonding pads 132 and the bonding layer may be substantially coplanar. The bonding pads 132 may be part of an interconnect structure of the second package component 130, in some cases. In some embodiments, the second package components 130 may be attached to the redistribution structure 120 by bonding the bonding pads 132 of the second package components 130 to corresponding conductive pads 124 of the redistribution structure 120 using metal-to-metal bonding, described in greater detail below.

In some embodiments, each second package component 130 is attached to the redistribution structure 120 over a corresponding first package component 110. A second package component 130 may partially or fully overlap (e.g., laterally or horizontally overlap) its corresponding first package component 110. In some embodiments, the lateral dimensions (e.g., length and/or width) of a second package component 130 may be smaller than the lateral dimensions of its corresponding first package component 110. In other words, the footprint (e.g. lateral area) of a second package component 130 may be smaller than the footprint of its corresponding first package component 110. In some embodiments, a second package component 130 may fully overlap its corresponding first package component 110 such that the first package component 110 laterally protrudes beyond the edges of the second package component 130. In other embodiments, the lateral dimensions of a second package component 130 may be about the same or greater than the lateral dimensions of its corresponding first package component 110. In some embodiments, a first package component 110 may have more than one corresponding second package component 130, and the corresponding second package components 130 may be similar or different types of components.

In some embodiments, the second package components 130 are different types of components than the first package components 110. As a non-limiting example, a second package component 130 may be a memory die and its corresponding first package component 110 may be a logic die. This is an example, and any suitable combinations of component types are possible. Using a first package component 110 and/or a second package component 130 (e.g., “package component(s) 110/130”) having different functionalities in this manner can reduce package size, improve efficiency, and improve performance.

In some embodiments, the optical bridge structures 60 may be attached to the redistribution structure 120 by bonding the bonding pads 52 of the optical bridge structures 60 to corresponding conductive pads 124 of the redistribution structure 120 using metal-to-metal bonding, described in greater detail below. After attaching the optical bridge structures 60 to the redistribution structure 120, waveguides 48 of the optical bridge structures 60 may be optically coupled to waveguides 126 of the redistribution structure 120. In this manner, optical signals may be transmitted between the optical bridge structures 60 and the redistribution structure 120. For example, an optical bridge structure 60 may receive optical signals from a waveguide 126 or may transmit optical signals into a waveguide 126.

In some embodiments, an optical bridge structure 60 may be arranged between two neighboring second package components 130, as shown in FIG. 11. In some embodiments, an optical bridge structure 60 may be placed such that it overlaps two neighboring first package components 110, as shown in FIG. 11. In some embodiments, an optical bridge structure 60 may be placed laterally between two neighboring first package components 110. In some embodiments, an optical bridge structure 60 may electrically communicate with one or more adjacent first package components 110 and/or second package components 130. For example, in some embodiments, an optical bridge structure 60 may receive electrical signals from an associated first package component 110 and/or an associated second package component 130 (e.g., “associated package component(s) 110/130”) and may transmit optical signals into a waveguide 126 based on the electrical signals. As another example, an optical bridge structure 60 may receive optical signals from a waveguide 126 and may transmit electrical signals to an associated package component 110/130 based on the optical signals.

In some embodiments, the second package components 130 and the optical bridge structures 60 may be bonded to the redistribution structure 120 using dielectric-to-dielectric bonding and metal-to-metal bonding (e.g., using fusion bonding). The second package components 130 and the optical bridge structures 60 may be bonded using one or more of the same process steps or may be bonded using separate process steps. The second package components 130 and the optical bridge structures 60 may be bonded simultaneously or in any suitable order or sequence. The bonding process may be similar to that described previously for FIG. 4. For example, in some embodiments, bonding layers of the second package components 130 and bonding layers 46 of the optical bridge structures 60 are bonded to a bonding layer of the redistribution structure 120 using a dielectric-to-dielectric bonding process, and bonding pads 132 of the second package components 130 and bonding pads 52 of the optical bridge structures 60 are bonded to corresponding conductive pads 124 of the redistribution structure 120 using a metal-to-metal bonding process.

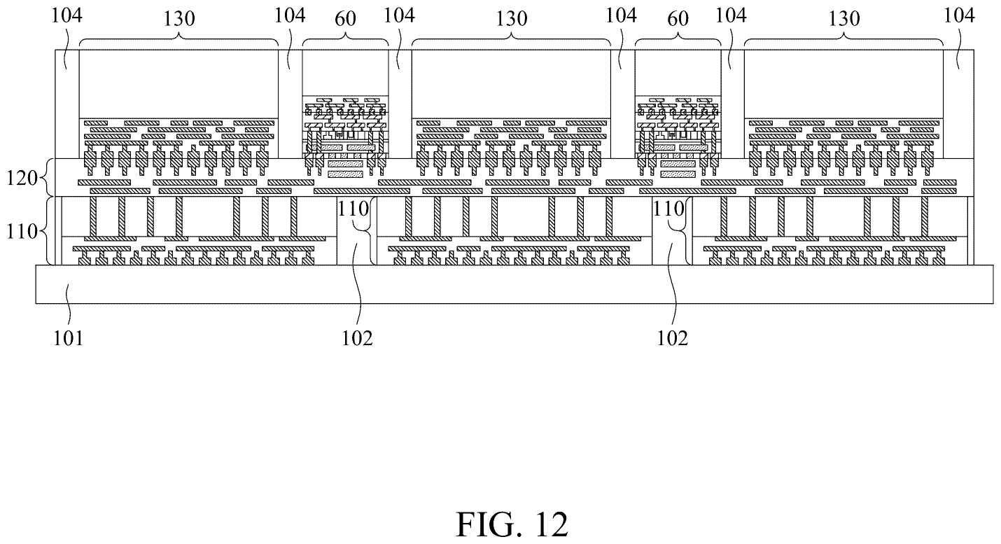

In FIG. 12, an encapsulant 104 is formed on and around the second package components 130 and the optical bridge structures 60, in accordance with some embodiments. After formation, the encapsulant 104 encapsulates the second package components 130 and the optical bridge structures 60. The encapsulant 104 may be a molding compound, an epoxy, a polymer, a composite material, a dielectric material, or the like, and may be similar to the encapsulant 102 in some cases. In some embodiments, the encapsulant 104 is applied by deposition, spin-on, compression molding, transfer molding, or the like. The encapsulant 104 may be formed over the redistribution structure 120 such that the second package components 130 and/or the optical bridge structures 60 are buried or covered. The encapsulant 104 may be applied in liquid or semi-liquid form and then subsequently cured.

In some embodiments, a planarization process is performed on the encapsulant 104 to expose the second package components 130 and/or the optical bridge structures 60. Top surfaces of the second package components 130, the optical bridge structures 60, and/or the encapsulant 104 may be substantially level or coplanar (within process variations) after performing the planarization process. The planarization process may comprise, for example, a CMP process, a grinding process, an etching process, or the like. In some embodiments, the planarization process may be omitted.

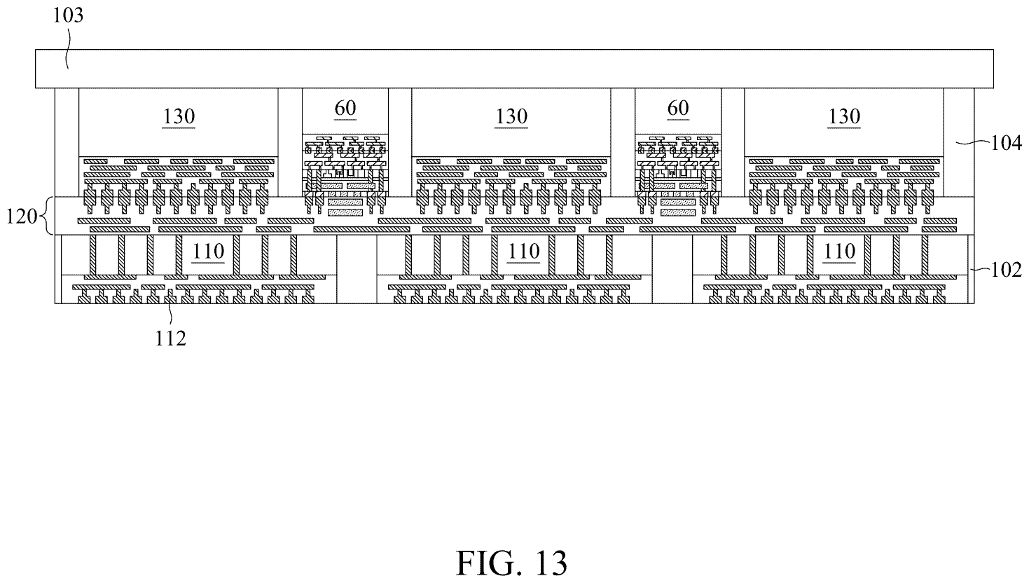

In FIG. 13, a second carrier 103 is attached to the structure and the first carrier 101 is removed, in accordance with some embodiments. The second carrier 103 is attached to the front side of the structure, and thus may be attached to the second package components 130, the optical bridge structures 60, and/or the encapsulant 104 in some cases. The second carrier 103 may be similar to the first carrier 101, and may be attached using an adhesive or other suitable technique. After attachment of the second carrier 103, the first carrier 101 is removed from the back side of the structure. Removing the first carrier 101 may expose the back side of the first package components 110 and the encapsulant 102, as shown in FIG. 13.

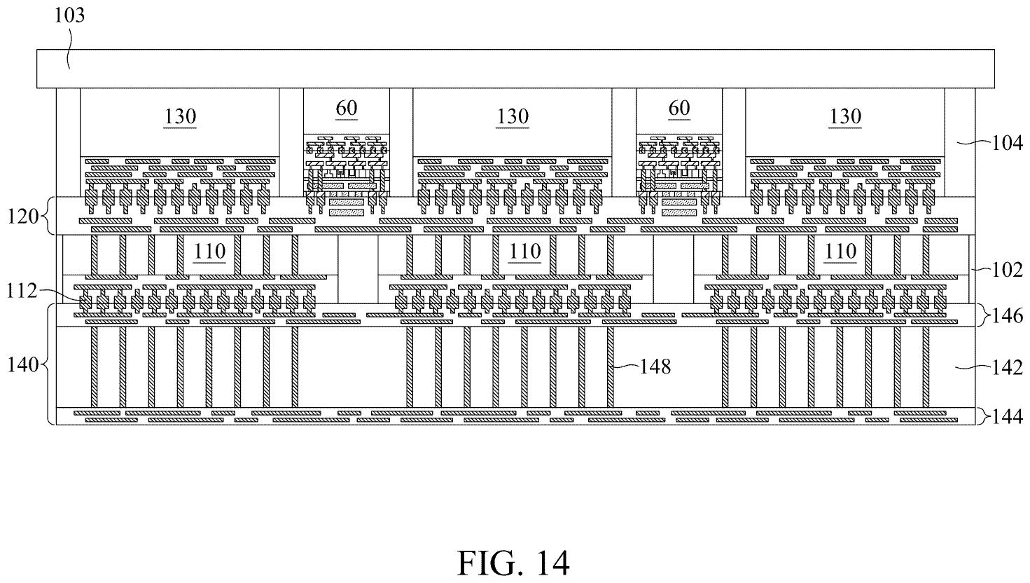

In FIG. 14, an interposer 140 is attached to the back side of the structure, in accordance with some embodiments. In some embodiments, the interposer 140 is bonded to the first package components 110 using dielectric-to-dielectric bonding and metal-to-metal bonding. For example, bonding pads 112 of the first package components 110 may be bonded to corresponding conductive pads (not separately labelled) of the interposer 140 using metal-to-metal bonding. In this manner, the interposer 140 is physically and electrically connected to the first package components 110.

In some embodiments, the interposer 140 comprises a substrate 142, a back side interconnect structure 144 on the back side of the substrate 142, a front side interconnect structure 146 on the front side of the substrate 142, and through vias 148 extending through the substrate 142. In other embodiments, the back side interconnect structure 144 or the front side interconnect structure 146 is not present. The interposer 140 shown is an example, and the interposer 140 may have another configuration in other embodiments. The interposer 140 may be substantially free of active and/or passive devices, in some embodiments.

The substrate 142 may be a semiconductor substrate (e.g., a silicon wafer) or another type of substrate, such as those described previously for the substrate 10 (see FIG. 1). In some embodiments, the substrate 142 may comprise an organic core or the like. Each interconnect structure 144/146 comprises one or more layers of conductive features formed in one or more dielectric layers (not individually illustrated). The conductive features may include conductive lines, conductive vias, conductive pads, metallization patterns, redistribution layers, or the like, which may be formed using any suitable technique such as deposition, damascene, dual damascene, or the like. In some embodiments, the front side interconnect structure 146 may comprise conductive pads that are bonded to corresponding bonding pads 112 of the first package components 110, as mentioned above. In some embodiments, the topmost dielectric layer of the front side interconnect structure 146 is a bonding layer that is bonded to bonding layers of the first package components 110 using dielectric-to-dielectric bonding. The through vias 148 of the interposer 140 extend through the substrate 142 and electrically connect the back side interconnect structure 144 to the front side interconnect structure 146. Other configurations of the back side interconnect structure 144, the front side interconnect structure 146, and/or the through vias 148 are possible.

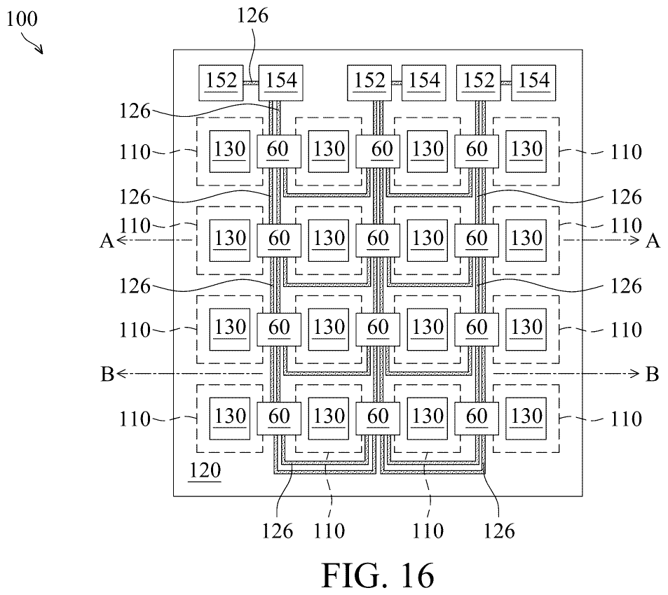

In FIGS. 15A and 15B, conductive connectors 150 are formed on the interposer 140 and the second carrier 103 is removed. In this manner, a package 100 may be formed, in accordance with some embodiments. FIGS. 15A and 15B illustrate parallel cross-sections of a package 100, which may be similar to the reference cross-sections A-A and B-B shown in FIG. 16 (described in greater detail below). In some embodiments, multiple packages 100 may be formed on the same first carrier 101, second carrier 103, and/or interposer 140 and then singulated into individual packages 100.

Conductive connectors 150 may be formed on the back side interconnect structure 144, in accordance with some embodiments. The conductive connectors 150 are physically and electrically connected to conductive features of the back side interconnect structure 144. The conductive connectors 150 may comprise, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 150 may include a conductive material such as solder, copper, aluminum, gold, nickel, silver, palladium, tin, the like, or a combination thereof. In some embodiments, the conductive connectors 150 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 150 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In some embodiments, the conductive connectors 150 comprise under-bump metallizations (UBMs). In other embodiments, the conductive connectors 150 are bonding pads used for metal-to-metal bonding to an external component.

FIG. 15A illustrates a package 100 in a cross-sectional view similar to those shown in FIGS. 8-14. FIG. 15B illustrates the same package 100 in a cross-sectional view parallel to the cross-sectional view of FIG. 15A but offset such that the first package components 110, the second package components 130, and the optical bridge structures 60 are not cross-sectioned. For reference, FIG. 15B illustrates the approximate locations of the first package components 110, second package components 130, and optical bridge structures 60 of FIG. 15A using dashed outlines. As shown in FIG. 15B, waveguides 126 of the redistribution structure 120 may extend from one optical bridge structure 60 to another optical bridge structure 60. In this manner, the waveguides 126 may transmit optical signals between the various optical bridge structures 60 of the package 100.

FIG. 16 illustrates a schematic plan view of a package 100, in accordance with some embodiments. The package 100 may be similar to the package 100 described for FIGS. 15A-15B. For example, the package 100 of FIG. 16 includes a redistribution structure 120 comprising waveguides 126, a plurality of first package components 110, a plurality of second package components 130, and a plurality of optical bridge structures 60. The redistribution structure 120, the first package components 110, the second package components 130, and the optical bridge structures 60 may be similar to those described for FIGS. 15A-15B. The cross-sectional view of FIG. 15A may correspond to a cross-section similar to that of the reference cross-section A-A shown in FIG. 16, and the cross-sectional view of FIG. 15B may correspond to a cross-section similar to that of the reference cross-section B-B shown in FIG. 16.

In some embodiments, the package 100 also includes optical devices 152 and optical engines 154 that are optically coupled to the waveguides 126. The optical devices 152 and optical engines 154 may be attached to the redistribution structure 120 or may be within the redistribution structure 120. The optical devices 152 may comprise, for example, laser diodes, III-V semiconductor devices, II-VI semiconductor devices, dies, chips, chiplets, or the like. The optical engines 154 may comprise, for example, photonic devices (e.g., PICs), dies, chips, chiplets, or the like. In this manner, the optical devices 152 may provide optical power into optical engines 154, and the optical engines 154 may control the optical power provided to the waveguides 126.

As shown in FIG. 16, each second package component 130 may be located over or near a corresponding first package component 110. Each first package component 110 may electrically communicate with its corresponding second package component 130 through the redistribution structure 120. The optical bridge structures 60 may be located between neighboring first package components 110 and/or between neighboring second package components 130. The first package component(s) 110 and/or second package component(s) 130 adjacent to an optical bridge structure 60 may be associated with that optical bridge structure 60 and may communicate electrically with that optical bridge structure 60. As shown in FIG. 16, each optical bridge structure 60 is optically connected to one or more other optical bridge structures 60 by the waveguides 126 of the redistribution structure 120. The waveguides 126 are utilized to transmit optical signals within the package 100, such as optical signals transmitted between optical bridge structures 60. In this manner, the waveguides 126 may be used to provide relatively long-distance communications within the package 100 using optical signals.

As an example, a first package component 110 and/or a second package component 130 (e.g., “package component(s) 110/130”) may transmit electrical signals to an associated optical bridge structure 60, which then uses its photonic components 18 to transmit corresponding optical signals to an optically coupled waveguide 126. The optical signals are transmitted by the waveguide 126 to a second optical bridge structure 60, where they may be received by the photonic components 18 of the second optical bridge structure 60. The second optical bridge structure 60 send then may transmit corresponding electrical signals to its associated package component(s) 110/130. This is an example, and other communication steps or signal processing operations are possible. In some embodiments, the optical bridge structures 60 may act as I/O interfaces between optical signals and electrical signals within a package 100, and may provide electric-optical conversion for a large area optical interconnect of the package 100. In this manner, by communicating electrical signals over short distances through the redistribution structure 120 and communicating optical signals over long distances using the waveguides 126 and the optical bridge structures 60, the efficiency, speed, and/or bandwidth of a package 100 may be improved, and manufacturing cost may be reduced.

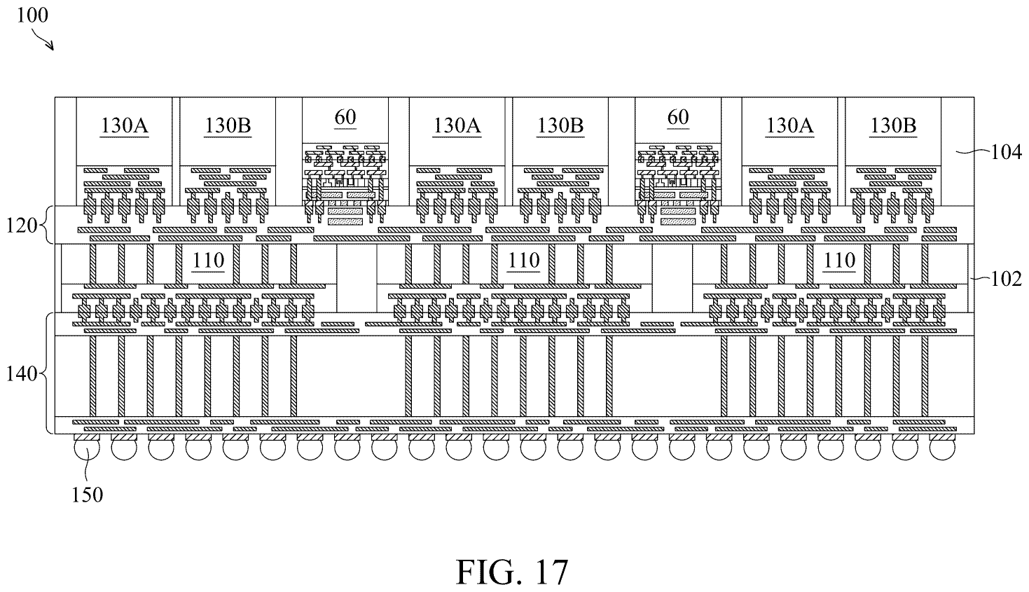

The packages 100 shown in FIGS. 15A, 15B, and 16 are illustrative examples, and other configurations of packages 100 are possible. As an example, FIG. 17 illustrates a package 100, in accordance with some embodiments. The package 100 of FIG. 17 is similar to the package 100 of FIG. 15A, except that each first package component 110 has two corresponding second package components 130A-B. The two second package components 130A-B may be attached over the first package component 110 and may be side-by-side. The second package components 130A and 130B may be similar or different types of components. For example, in some embodiments, both second package components 130A and 130B may be processing chiplets (e.g., xPUs), but other combinations are possible. In other embodiments, more than two second package components 130 may correspond to each first package component 110, and different first package components 110 may have different numbers of corresponding second package components 130. For example, in some embodiments, between 1 and 16 second package components 130 may correspond to each first package component 110, though another number of second package components 130 are possible. In some cases, all of the second package components 130 corresponding to a single first package component 110 may be fully overlapped by the first package component 110.

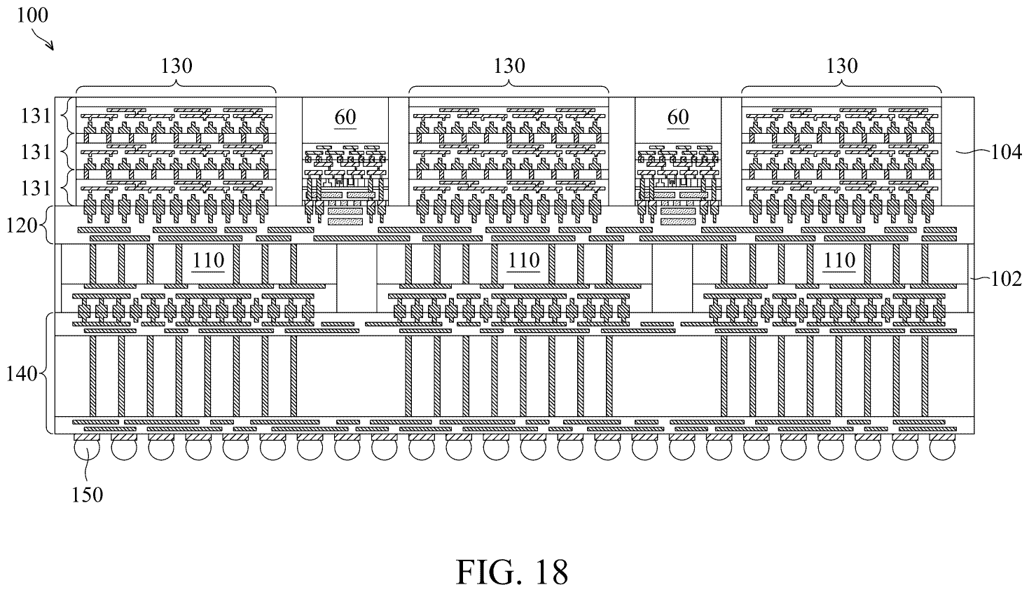

As another example, FIG. 18 illustrates a package 100, in accordance with some embodiments. The package 100 of FIG. 18 is similar to the package 100 of FIG. 15A, except that the second package components 130 are stacked structures. For example, the second package components 130 of FIG. 18 comprise three chiplets 131 that are bonded into a single stacked structure. Other numbers of chiplets 131 or configurations of stacked structures are possible. As an example, the second package components 130 may be a High-Bandwidth Memory (HBM) dies, in some embodiments. Other types of stacked structures are possible.

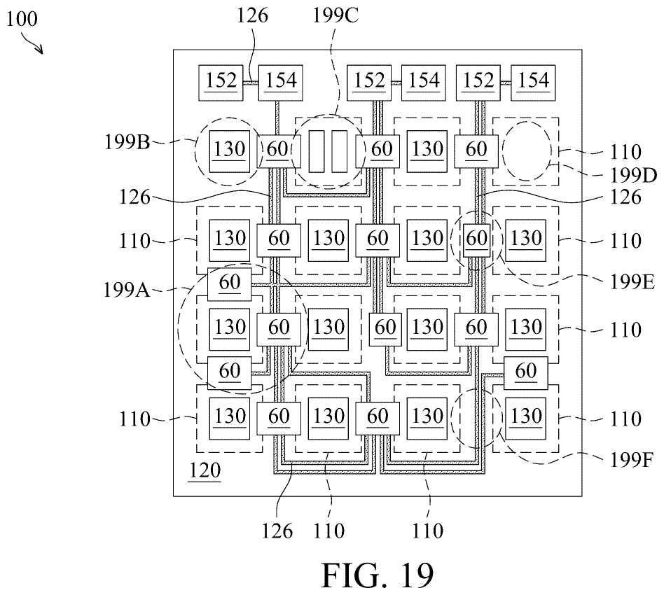

The number, arrangement, or configuration of first package components 110, second package components 130, optical bridge structures 60, and/or waveguides 126 of a package 100 may have any suitable variations. As a non-limiting example, FIG. 19 illustrates a schematic plan view of a package 100, in accordance with some embodiments. The package 100 of FIG. 19 is similar to the package 100 of FIG. 16, but has a different arrangement of some features. While FIG. 16 illustrates a package 100 in which the optical bridge structures 60 are arranged in rows between neighboring second package components 130, the optical bridge structures 60 may be arranged in any suitable configuration. As an illustrative example, region 199A of FIG. 19 shows optical bridge structures 60 arranged on various sides of a second package component 130. In other words, the optical bridge structures 60 may be arranged in rows and/or in columns between neighboring second package components 130 as desired. In some embodiments, one or more second package components 130 may not have a corresponding first package component 110, such as the illustrative example shown in region 199B. Region 199C of FIG. 19 illustrates multiple second package components 130 corresponding to a single first package component 110, similar to the embodiment described for FIG. 17. In some embodiments, one or more first package components 110 may not have a corresponding second package component 130, such as the illustrative example shown in region 199D. In some embodiments, an optical bridge structure 60 may not laterally overlap first package components 110, such as the illustrative example shown in region 199E. In some cases, an optical bridge structure 60 may overlap only a single first package component 110. In some embodiments, an optical bridge structure 60 may not be present between package components 110/130, such as the illustrative example shown in region 199F. Additionally, the waveguides 126 of the redistribution structure 120 may have any number, configuration, or arrangement that provides suitable optical interconnection for the optical bridge structures 60 of a package 100.

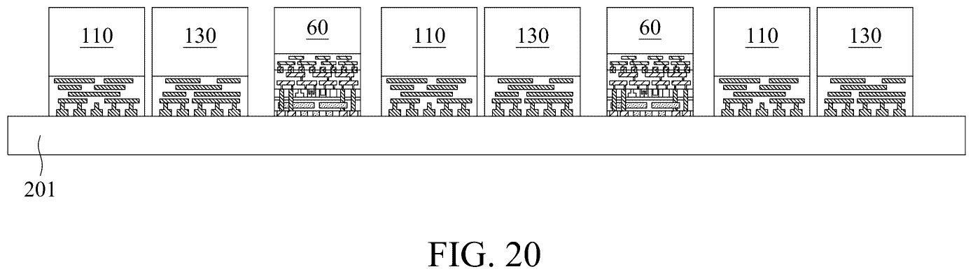

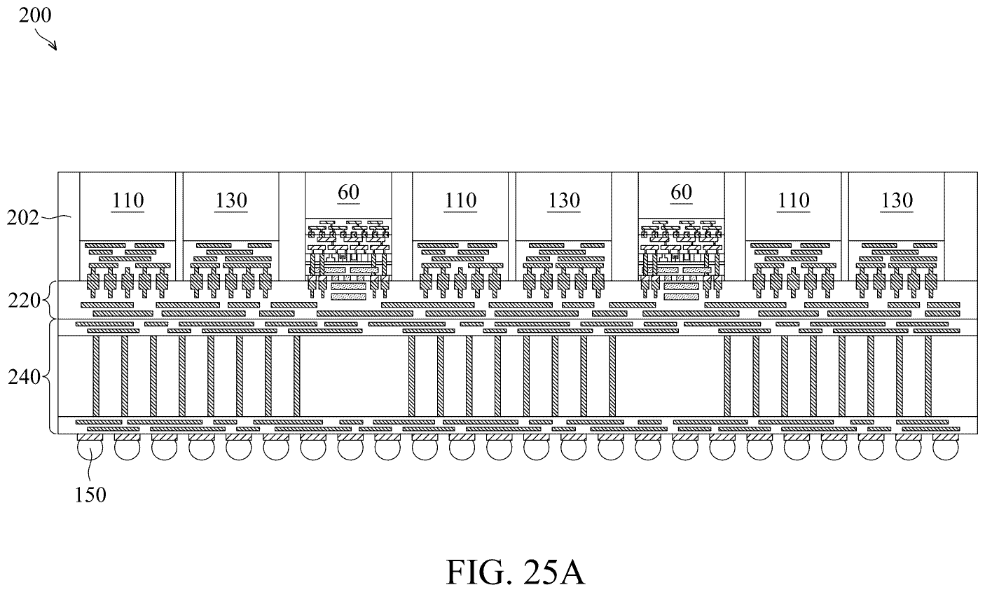

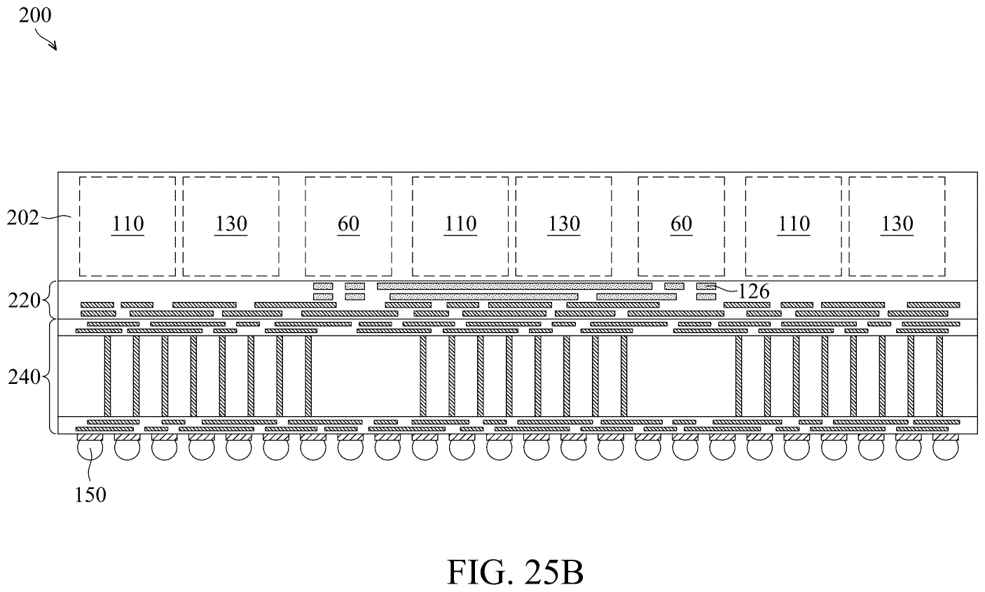

FIGS. 20 through 25A-25B illustrate intermediate stages in the formation of a package 200 (see FIGS. 25A-25B), in accordance with some embodiments. The package 200 is similar to the package 100, except that the first package components 110, the second package components 130, and the optical bridge structures 60 are attached to the same side of a redistribution structure 220. Some features or manufacturing steps of the package 200 may be similar to those described previously for the package 100, and accordingly some details may not be repeated.

In FIG. 20, a plurality of first package components 110, a plurality of second package components 130, and a plurality of optical bridge structures 60 are attached to a first carrier 201, in accordance with some embodiments. The first package components 110, the second package components 130, and the optical bridge structures 60 may be similar to those described previously for the package 100. For example, the first package components 110 may be different types of components than the second package components 130. The first carrier 201 may be similar to the first carrier 101 described previously.

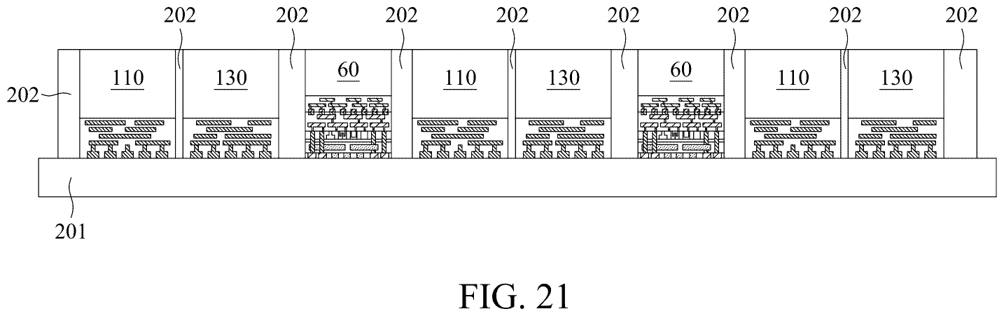

In FIG. 21, an encapsulant 202 is formed on and around the first package components 110, the second package components 130, and the optical bridge structures 60, in accordance with some embodiments. After formation, the encapsulant 202 encapsulates the first package components 110, the second package components 130, and the optical bridge structures 60. The encapsulant 202 may be similar to the encapsulant 102 described previously for the package 100. The encapsulant 202 may be formed over the first carrier 201 such that the first package components 110, the second package components 130, and/or the optical bridge structures 60 are buried or covered. The encapsulant 202 may be applied in liquid or semi-liquid form and then subsequently cured.

In some embodiments, a planarization process is performed on the encapsulant 202 to expose the first package components 110, the second package components 130, and/or the optical bridge structures 60. Top surfaces of the first package components 110, the second package components 130, the optical bridge structures 60, and/or the encapsulant 202 may be substantially level or coplanar (within process variations) after performing the planarization process. The planarization process may comprise, for example, a chemical-mechanical polish (CMP) process, a grinding process, an etching process, or the like. In some embodiments, the planarization may be omitted.

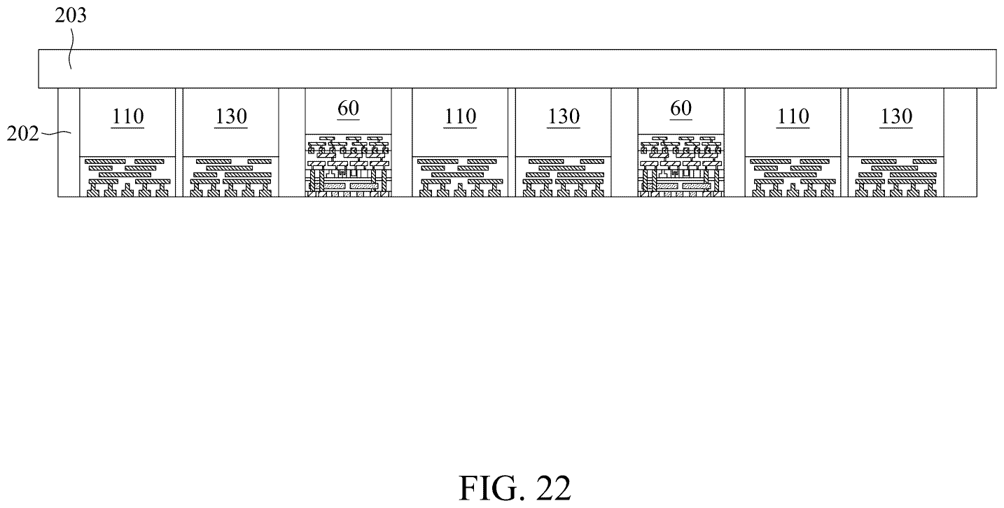

In FIG. 22, a second carrier 203 is attached to the front side of the structure and the first carrier 201 is removed, in accordance with some embodiments. The second carrier 203 may be similar to the second carrier 103 described previously, and may be attached using an adhesive or the like. After removing the first carrier 201, back side surfaces of the first package components 110, the second package components 130, the optical bridge structures 60, and the encapsulant 202 are exposed, and may be substantially level or coplanar.

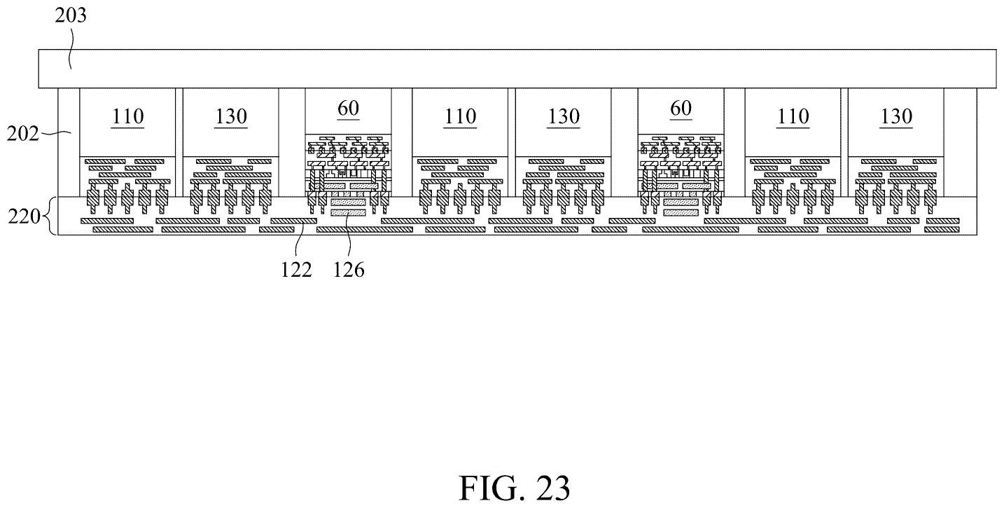

In FIG. 23, a redistribution structure 220 is formed over the back side of the structure, in accordance with some embodiments. The redistribution structure 220 may be similar to the redistribution structure 120 described previously, and may be formed using similar materials or techniques. For example, the redistribution structure 220 may comprise a plurality of conductive features 122 and a plurality of waveguides 126 formed in a plurality of dielectric layers. The conductive features 122 and the waveguides 126 may be similar to those described previously. For example, the conductive features 122 make electrical connections to the first package components 110, the second package components 130, and the optical bridge structures 60, and some waveguides 126 may be optically coupled to optical bridge structures 60.

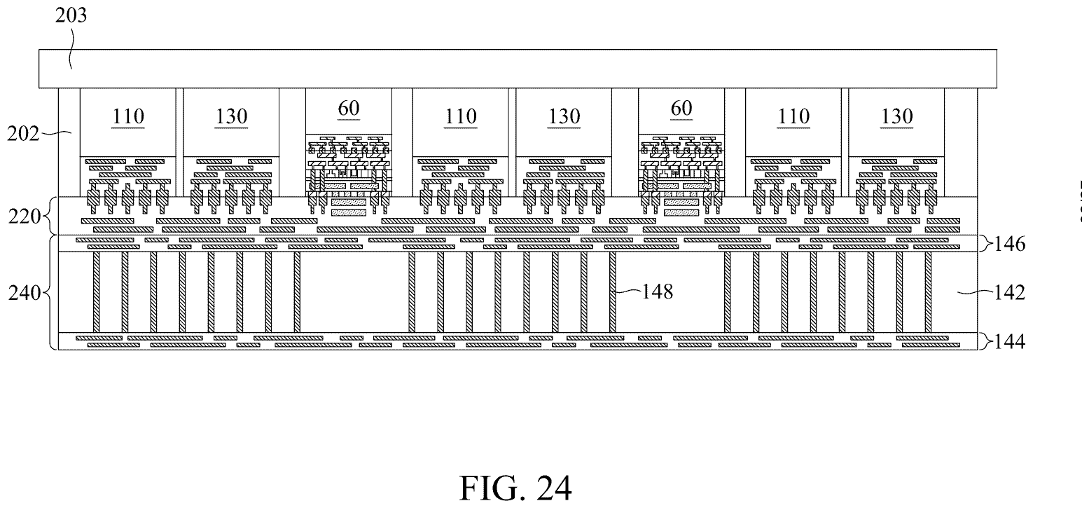

In FIG. 24, an interposer 240 is bonded to the redistribution structure 220, in accordance with some embodiments. The interposer 240 may be similar to the interposer 140 described previously. For example, in some embodiments, the interposer 240 comprises a substrate 142, a back side interconnect structure 144, a front side interconnect structure 146, and through vias 148. In other embodiments, the interposer 240 may have a different configuration than shown. For example, in other embodiments, only one of the back side interconnect structure 144 or the front side interconnect structure 146 may be present. In some embodiments, the interposer 240 is bonded to the redistribution structure 220 using dielectric-to-dielectric bonding and metal-to-metal bonding. In this manner, the interposer 240 is physically and electrically connected to the redistribution structure 220.

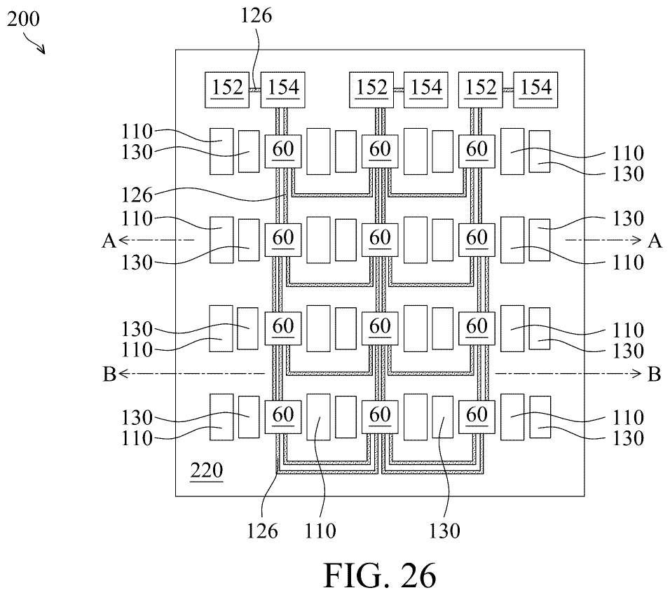

In FIGS. 25A and 25B, conductive connectors 150 are formed on the interposer 240 and the second carrier 203 is removed. In this manner, a package 200 may be formed, in accordance with some embodiments. FIGS. 25A and 25B illustrate parallel cross-sections of a package 200, which may be similar to the reference cross-sections A-A and B-B shown in FIG. 26 (described in greater detail below). In some embodiments, multiple packages 200 may be formed on the same first carrier 201, second carrier 203, and/or interposer 240 and then singulated into individual packages 200.

FIG. 26 illustrates a schematic plan view of a package 200, in accordance with some embodiments. The package 200 may be similar to the package 200 described for FIGS. 25A-25B. For example, the package 200 of FIG. 26 includes a redistribution structure 220 comprising waveguides 126, a plurality of first package components 110 attached to the front side of the redistribution structure 220, a plurality of second package components 130 attached to the front side of the redistribution structure 220, and a plurality of optical bridge structures 60 attached to the front side of the redistribution structure 220. The cross-sectional view of FIG. 25A may correspond to a cross-section similar to that of the reference cross-section A-A shown in FIG. 26, and the cross-sectional view of FIG. 25B may correspond to a cross-section similar to that of the reference cross-section B-B shown in FIG. 26.

As shown in FIG. 26, each first package component 110 may be located adjacent to a corresponding second package component 130. Each first package component 110 may electrically communicate with its corresponding second package component 130 through the redistribution structure 120. The optical bridge structures 60 may be located between neighboring sets of package components 110/130. As shown in FIG. 26, each optical bridge structure 60 is optically connected to one or more other optical bridge structures 60 by the waveguides 126 of the redistribution structure 220. The waveguides 126 are utilized to transmit optical signals within the package 200, such as optical signals transmitted between optical bridge structures 6o. In this manner, the waveguides 126 may be used to provide relatively long-distance communications within the package 200 using optical signals.

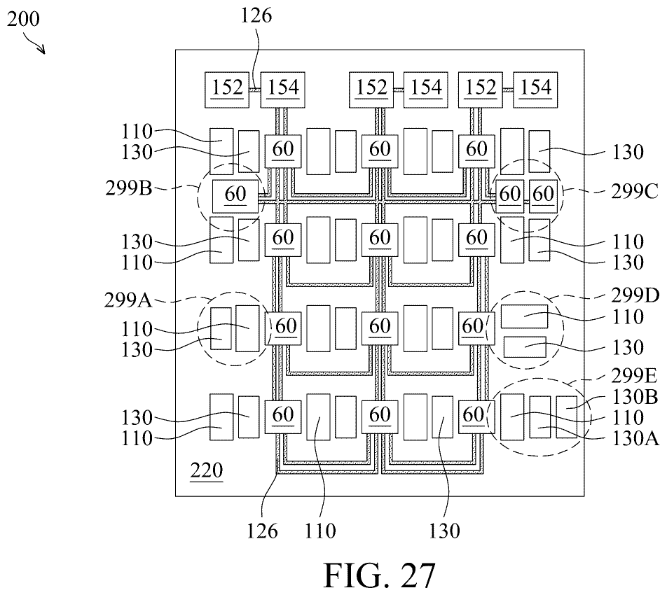

The number, arrangement, or configuration of first package components 110, second package components 130, optical bridge structures 60, and/or waveguides 126 of a package 200 may have any suitable variations. As a non-limiting example, FIG. 27 illustrates a schematic plan view of a package 200, in accordance with some embodiments. The package 200 of FIG. 27 is similar to the package 200 of FIG. 26, but has a different arrangement of some features. For example, the package components 110/130 may have any suitable arrangement as shown by regions 299A and 299D of FIG. 27. While FIG. 26 illustrates a package 200 in which the optical bridge structures 60 are arranged in rows between neighboring sets of package components 110/130, the optical bridge structures 60 may be arranged in any suitable configuration, such as the arrangements shown in regions 299B and 299C of FIG. 27. Region 299E of FIG. 27 illustrates multiple second package components 130A-B corresponding to a single first package component 110. In other embodiments, one or more first package components 110 may not have a corresponding second package component 130, or one or more second package components 130 may not have a corresponding first package component 110. Additionally, the waveguides 126 of the redistribution structure 220 may have any number, configuration, or arrangement that provides suitable optical interconnection for the optical bridge structures 60 of a package 200.

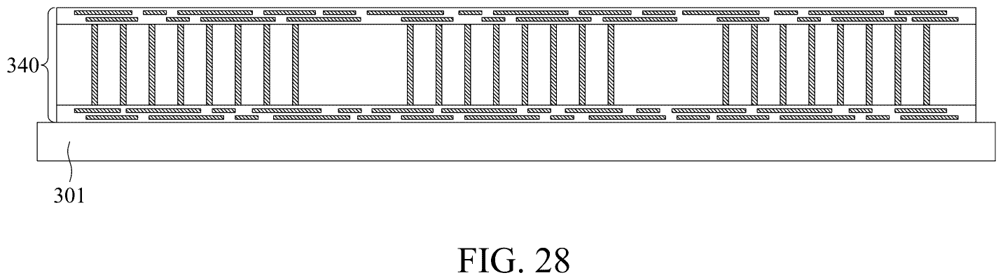

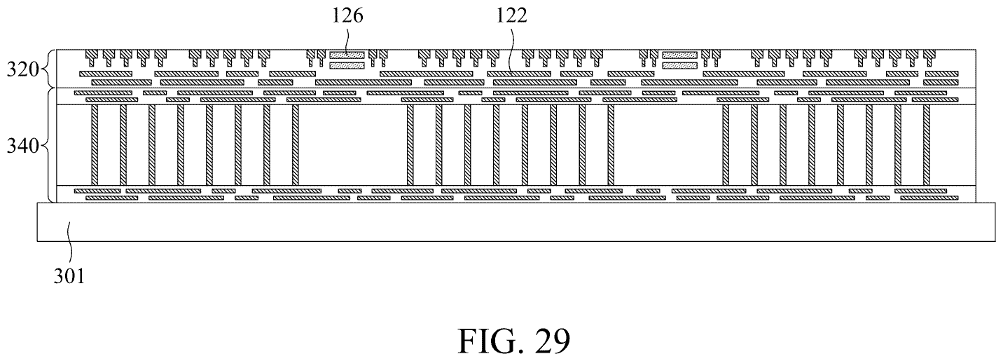

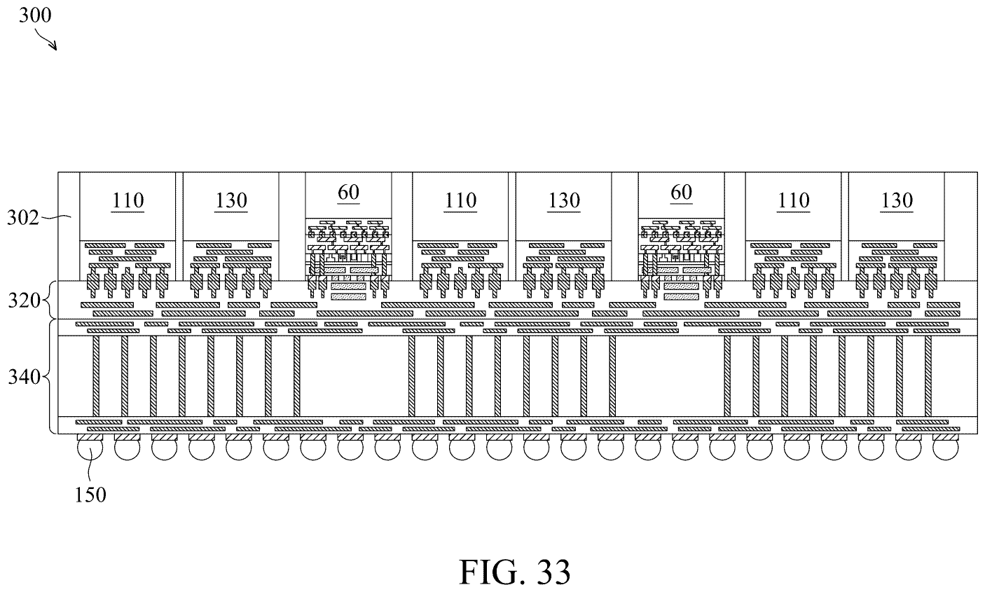

FIGS. 28 through 33 illustrate intermediate stages in the formation of a package 300 (see FIG. 33), in accordance with some embodiments. The package 300 is similar to the package 200 described above for FIGS. 25A-25B. Some features or manufacturing steps of the package 300 may be similar to those described previously for the packages 100 or 200, and accordingly some details may not be repeated.

In FIG. 28, an interposer 340 is attached to a first carrier 301, in accordance with some embodiments. The interposer 340 may be similar to the interposer 240 described previously. The first carrier 301 may be similar to the first carrier 201 described previously.

In FIG. 23, a redistribution structure 320 is formed over the front side of the structure, in accordance with some embodiments. The redistribution structure 320 is physically and electrically connected to the interposer 340. The redistribution structure 320 may be similar to the redistribution structures 120 or 220 described previously, and may be formed using similar materials or techniques. For example, the redistribution structure 320 may comprise a plurality of conductive features 122 and a plurality of waveguides 126 formed in a plurality of dielectric layers. The conductive features 122 and the waveguides 126 may be similar to those described previously.

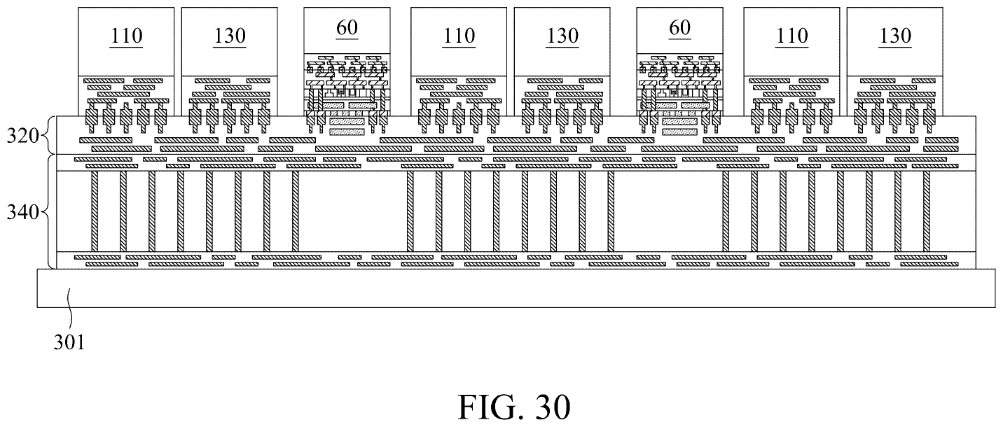

In FIG. 30, a plurality of first package components 110, a plurality of second package components 130, and a plurality of optical bridge structures 60 are attached to the redistribution structure 320, in accordance with some embodiments. The first package components 110, the second package components 130, and the optical bridge structures 60 may be similar to those described previously for the package 100. For example, the first package components 110 may be different types of components than the second package components 130. The first package components 110, the second package components 130, and the optical bridge structures 60 may be attached to the redistribution structure 320 using dielectric-to-dielectric bonding and metal-to-metal bonding, in some embodiments. The optical bridge structures 60 may be optically coupled to waveguides 126 of the redistribution structure 320 after bonding.

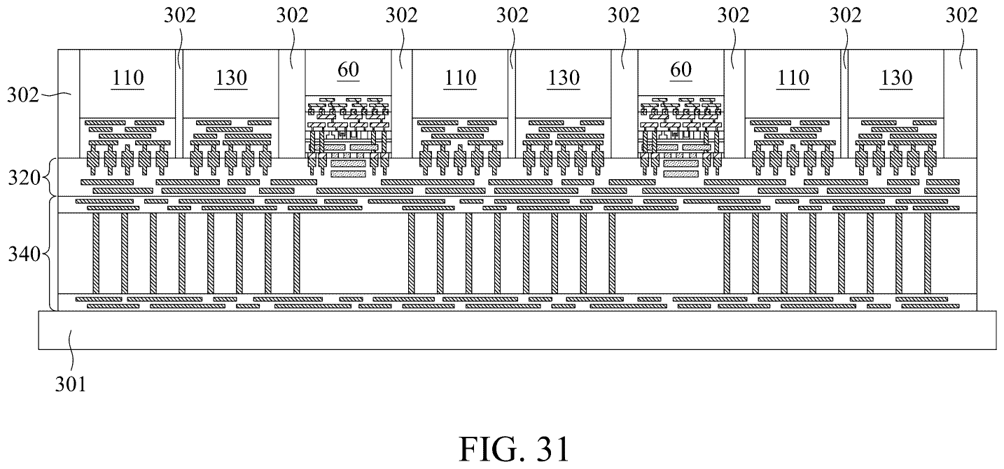

In FIG. 31, an encapsulant 302 is formed on and around the first package components 110, the second package components 130, and the optical bridge structures 60, in accordance with some embodiments. After formation, the encapsulant 302 encapsulates the first package components 110, the second package components 130, and the optical bridge structures 60. The encapsulant 302 may be similar to the encapsulant 102 described previously for the package 100. The encapsulant 302 may be formed over the redistribution structure 320 such that the first package components 110, the second package components 130, and/or the optical bridge structures 60 are buried or covered. The encapsulant 302 may be applied in liquid or semi-liquid form and then subsequently cured.

In some embodiments, a planarization process is performed on the encapsulant 302 to expose the first package components 110, the second package components 130, and/or the optical bridge structures 60. Top surfaces of the first package components 110, the second package components 130, the optical bridge structures 60, and/or the encapsulant 302 may be substantially level or coplanar (within process variations) after performing the planarization process. The planarization process may comprise, for example, a chemical-mechanical polish (CMP) process, a grinding process, an etching process, or the like. In some embodiments, the planarization may be omitted.

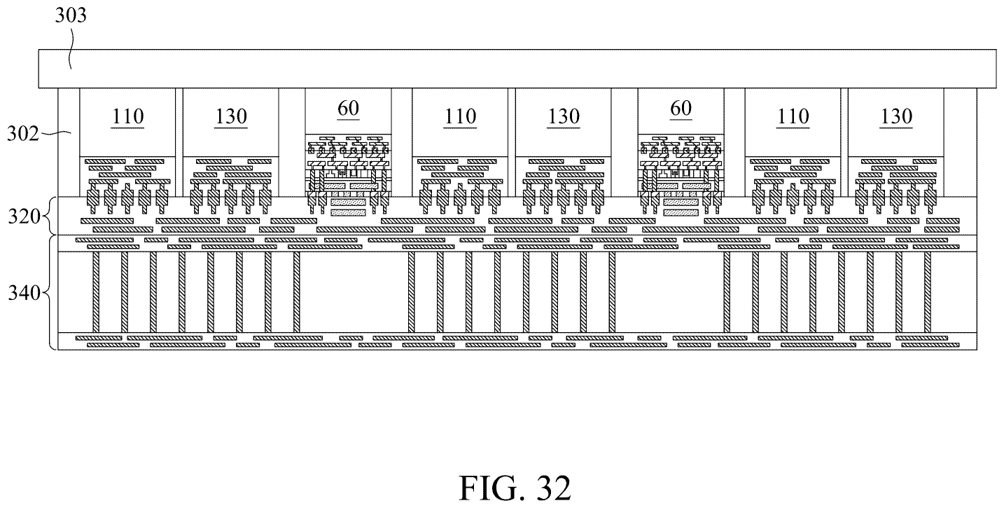

In FIG. 32, a second carrier 303 is attached to the front side of the structure and the first carrier 301 is removed, in accordance with some embodiments. The second carrier 303 may be similar to the second carrier 103 described previously, and may be attached using an adhesive or the like. For example, the second carrier 303 may be attached to front side surfaces of the first package components 110, the second package components 130, the optical bridge structures 60, and the encapsulant 302.

In FIG. 33, conductive connectors 150 are formed on the interposer 340 and the second carrier 303 is removed. In this manner, a package 300 may be formed, in accordance with some embodiments. The conductive connectors 150 may be similar to those described previously.

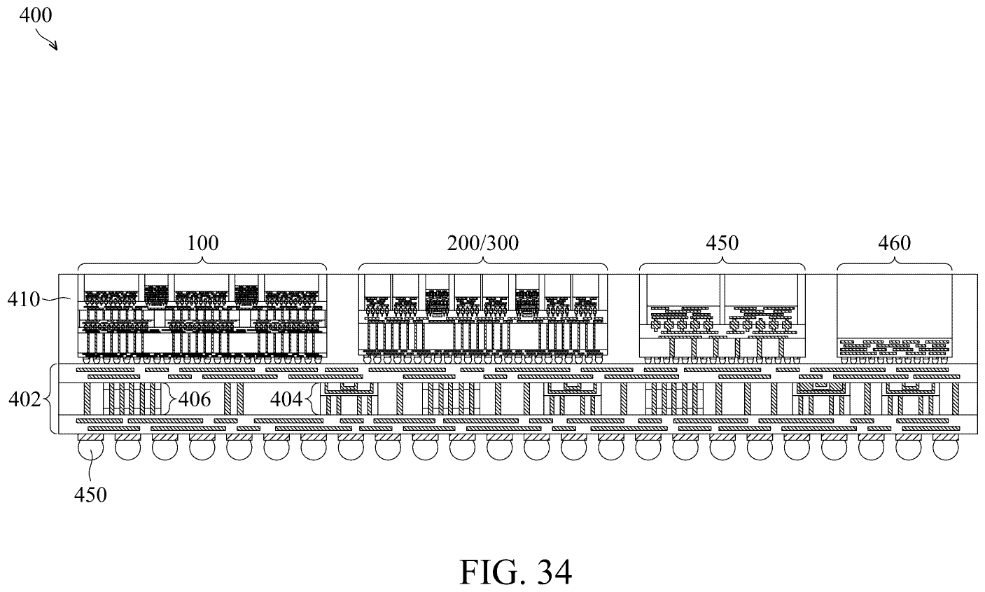

In some embodiments, the various embodiments of packages 100/200/300 described above may be incorporated into a larger package or system. FIG. 34 illustrates a system 400 that incorporates some of the packages 100/200/300 described herein. FIG. 34 illustrates a single package 100 and a single package 200/300 attached to the interconnect structure 402, but other numbers, arrangements, types, or configurations of packages are possible. The system 400 is also shown having a package 450 and a die 460 attached to the interconnect structure 402. The system 400 is intended as a representative example, and a system may comprise other embodiment packages, components, or features in any suitable configuration or arrangement. In some embodiments, the system 400 may be a Chip-on-Wafer-on-Substrate (CoWoS) structure or the like. In some embodiments, an encapsulant 410 is deposited over the package(s) 100/200/300, packages 450, and/or dies 460. The encapsulant may be similar to the encapsulant 102, for example. A planarization process may be performed to expose surfaces of the package(s) 100/200/300, packages 450, and/or dies 460, in some embodiments.

In some embodiments, the system 400 comprises an interconnect substrate 402. The interconnect substrate 402 may include conductive pads, conductive routing, conductive vias, metallization layers, redistribution layers, or other conductive features that provide interconnections and electrical routing. In some cases, the interconnect substrate 402 may include interconnect structure(s) formed on the front side and/or the back side of a core substrate. In some cases, the interconnect substrate 402 is a redistribution structure without a core substrate. In some embodiments, the interconnect substrate 402 may comprise an interposer, a semiconductor substrate (e.g., a wafer), one or more redistribution structures, an organic substrate, a glass substrate, a printed circuit board (PCB), or the like. The interconnect substrate 402 may or may not comprise active and/or passive devices.

In some cases, the interconnect substrate 402 may comprise local interconnects 404. The local interconnects 404 may be, for example, chips, chiplets, local silicon interconnects (LSIs), interconnect structures, or the like, which provide additional electrical interconnections within the interconnect substrate 402. The local interconnects 404 may include conductive features (e.g., conductive lines, vias, pads, or the like) formed in dielectric layers. The conductive features may be formed using suitable techniques, such as damascene, dual damascene, or the like. For example, in some cases, a local interconnect 404 may comprise an interconnect structure on a substrate, which may have through vias within, though other local interconnects 404 are possible. In some cases, the conductive features of the local interconnects 404 may have a smaller linewidth and/or pitch than the conductive features of the interconnect substrate 402. The local interconnects 404 may or may not include passive devices or active devices. The local interconnects 404 shown in FIG. 34 are illustrative examples, and other local interconnects 404 or configurations thereof are possible. In some cases, the interconnect substrate 402 does not include local interconnects 404.

In some cases, the interconnect substrate 402 may comprise integrated devices 406. The integrated devices 406 may be, for example, integrated passive devices (IPDs), integrated voltage regulators (IVRs), or the like. In some cases, the integrated devices 406 may be surface mount devices (SMDs). The integrated devices 406 may be formed within the interconnect substrate 402 or may be attached to a surface of the interconnect substrate 402. The integrated devices 406 shown in FIG. 34 are illustrative examples, and other integrated devices 406 or configurations thereof are possible. In some cases, the interconnect substrate 402 does not include integrated devices 406.

As shown in FIG. 34, various packages 100/200/300 may be attached to the interconnect structure 402 by the conductive connectors 150. For example, the conductive connectors 150 of a package 100/200/300 may be placed on corresponding conductive features of the interconnect structure 402 and then a reflow process may be performed to bond the conductive connectors 150 to the interconnect structure 402. In some embodiments, an underfill (not illustrated) may be deposited between a package 100/200/300 and the interconnect structure 402.

Other dies, packages, or devices may be attached to the interconnect substrate 402 in addition to one or more packages 100/200/300. This is illustrated in FIG. 34 by package 450 and die 460 attached to the interconnect structure 402, though packages 450 or dies 460 may have a different number, arrangement, types, or configurations than shown. In other embodiments, packages 450 and/or dies 460 are not present. In some cases, the package 450 may comprise one or more dies attached to an interposer. For example, a package 450 may comprise a processing die and a memory die attached to an interposer, though other configurations or types of dies are possible. In some cases, a package 450 may be a System-on-Integrated-Circuit (SoIC) package or the like. The dies 460 may be similar or different types of dies that are attached to the interconnect structure 402. For example, a processing die 460 and a memory die 460 may be attached to the interconnect structure, but other numbers or types of dies are possible. In this manner, various packages 100/200/300 described herein can be combined with other structures of a system 400 and can allow for improved performance of a system 400.

Embodiments of the present disclosure have some advantageous features. The use of an optical bridge structures as described herein can enable intra-package optical communication. The use of optical bridge structures can reduce manufacturing cost, reduce package size, and enable optical communication between various dies or devices of a package. This can allow for more dies or devices to be optically connected within a single package. By using electrical signals over short distances and optical signals over long distances as described herein, the efficiency, speed, and/or bandwidth of a package may be improved. Additionally, using optical communication can generate less heat than electrical communication, thus the embodiments described herein can reduce the heat generated by a package. The embodiments described herein can facilitate both electrical communication and optical communication within a package, which can improve performance and efficiency.

In an embodiment of the present disclosure, a package includes a redistribution structure that includes conductive features and first waveguides; first dies and second dies attached to the redistribution structure, wherein the first dies are different than the second dies, wherein the first dies are electrically connected to respectively corresponding second dies through the redistribution structure; and optical bridge structures attached to the redistribution structure, wherein the optical bridge structures are optically coupled to the first waveguides, wherein the optical bridge structures are electrically connected to respectively corresponding first dies and respectively corresponding second dies through the redistribution structure. In an embodiment, the first dies are attached to a first side of the redistribution structure and second dies are attached to a second side of the redistribution structure. In an embodiment, the optical bridge structures are attached to the second side of the redistribution structure. In an embodiment, the optical bridge structures are between pairs of neighboring second dies. In an embodiment, at least one first waveguide is optically coupled to two or more optical bridge structures. In an embodiment, the first dies, the second dies, and the optical bridge structures are attached to the same side of the redistribution structure. In an embodiment, the package includes an interposer attached to the redistribution structure. In an embodiment, an encapsulant laterally separates second dies from adjacent optical bridge structures.

In an embodiment of the present disclosure, a package includes an interposer; a first package component attached to a front side of the interposer; a redistribution structure on a front side of the first package component, wherein the redistribution structure includes a first waveguide; a second package component attached to the front side of the redistribution structure, wherein the second package component laterally overlaps the first package component; and a first optical package component attached to the front side of the redistribution structure adjacent the second package component, wherein the first optical package component includes a second waveguide that is optically coupled to the first waveguide. In an embodiment, the second package component is fully laterally overlapped by the first package component. In an embodiment, the first optical package component laterally overlaps the first package component. In an embodiment, the package includes an encapsulant laterally surrounding the first package component. In an embodiment, the redistribution structure extends over the encapsulant. In an embodiment, the first package component is a processing die and the second package component is a memory die. In an embodiment, the package includes a third package component attached to the front side of the redistribution structure, wherein the third package component laterally overlaps the first package component. In an embodiment, the package includes a second optical package component attached to the front side of the redistribution structure, wherein the second optical package component is optically coupled to the first waveguide.

In an embodiment of the present disclosure, a method includes forming an optical bridge structure, which includes forming first waveguides; forming photonic components over the first waveguides; forming an interconnect structure over the photonic components; and bonding an electronic die to the interconnect structure; forming a redistribution structure on a first semiconductor die, wherein forming the redistribution structure includes forming second waveguides and conductive features within insulating layers; bonding the optical bridge structure to the redistribution structure using fusion bonding, wherein the first waveguides are optically coupled to the second waveguides after bonding; and bonding a second semiconductor die to the redistribution structure using fusion bonding. In an embodiment, the first semiconductor die and the second semiconductor die are on opposite sides of the redistribution structure. In an embodiment, the first semiconductor die and the second semiconductor die are free of waveguides. In an embodiment, the method includes bonding an interposer to the first semiconductor die using fusion bonding.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a redistribution structure comprising a plurality of conductive features and a plurality of first waveguides;
a plurality of first dies attached to a first side of the redistribution structure;
a plurality of second dies attached to a second side of the redistribution structure, wherein the first dies are different than the second dies, wherein the first dies are electrically connected to respectively corresponding second dies through the redistribution structure; and
a plurality of optical bridge structures attached to the redistribution structure, wherein the optical bridge structures are optically coupled to the plurality of first waveguides, wherein the optical bridge structures are electrically connected to respectively corresponding first dies and respectively corresponding second dies through the redistribution structure, wherein the optical bridge structures are between pairs of neighboring second dies.
